(19) United States
(12) Patent Application Publication
(10) Pub. No.: US 2026/0076202 A1
(43) Pub. Date: Mar. 12, 2026

(54) PACKAGE AND FABRICATION METHOD THEREOF

(71) Applicant: Taiwan Semiconductor Manufacturing Company, Ltd., Hsinchu (TW)

(72) Inventors: Kuan-Lin Ho, Hsinchu City (TW); Leu-Jen Chen, Taipei (TW); Chun-Chih Chuang, Taichung City (TW); Jung-Wei Cheng, Hsinchu City (TW); Hsien-Pin Hu, Hsinchu County (TW); Shang-Yun Hou, Hsinchu (TW); Kuo-Lung Pan, Hsinchu city (TW)

(73) Assignee: Taiwan Semiconductor Manufacturing Company, Ltd., Hsinchu (TW)

(21) Appl. No.: 18/830,479

(22) Filed: Sep. 10, 2024

(51) Int. Cl. H01L 23/00; H01L 21/48; H01L 23/367; H01L 23/538; H01L 25/16

(52) U.S. Cl. CPC H10W 42/121; H10W 40/22; H10W 70/60; H10W 70/611; H10W 90/00; H10W 99/00; H10W 72/072; H10W 72/073; H10W 72/07331; H10W 74/15; H10W 90/724; H10W 90/734

(57) ABSTRACT

A package includes a substrate, a first package component, second package components and a supporting structure. The first package component and the second package components are bonded to the substrate. The second package components are electrically connected to the first package component. Each of the second package components includes a n optical coupler. The supporting structure is attached on the substrate. At least a portion of the supporting structure is laterally located between the first package component and the second package components.

### BACKGROUND

The semiconductor industry has experienced rapid growth due to continuous advancements in the integration density of various electronic components, such as transistors, diodes, resistors, and capacitors. This improvement in integration density is primarily driven by the iterative reduction of minimum feature sizes, enabling more components to be incorporated into a given area. With the increasing demand for smaller electronic devices, there is a rising need for innovative and compact packaging techniques for semiconductor dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate top and cross-sectional views of a package in accordance with an embodiment of the disclosure.

FIGS. 2A, 2B and 2C illustrate top and cross-sectional views of a package in accordance with an embodiment of the disclosure.

FIG. 3 illustrates a cross-sectional view of a package in accordance with an embodiment of the disclosure.

FIG. 4 illustrates a cross-sectional view of a package in accordance with an embodiment of the disclosure.

FIG. 5 illustrates a cross-sectional view of a package in accordance with an embodiment of the disclosure.

FIGS. 6A and 6B illustrate top and cross-sectional views of a package in accordance with an embodiment of the disclosure.

FIGS. 7A and 7B illustrate top and cross-sectional views of a package in accordance with an embodiment of the disclosure.

FIGS. 8A, 8B and 8C illustrate top and cross-sectional views of a package in accordance with an embodiment of the disclosure.

FIG. 9 illustrates a cross-sectional view of a package in accordance with an embodiment of the disclosure.

FIG. 10 illustrates a cross-sectional view of a package in accordance with an embodiment of the disclosure.

FIG. 11 illustrates a cross-sectional view of a package in accordance with an embodiment of the disclosure.

FIGS. 12A and 12B illustrate cross-sectional views of a package in accordance with an embodiment of the disclosure.

FIG. 13 illustrates a cross-sectional view of a package in accordance with an embodiment of the disclosure.

FIGS. 14A and 14B illustrate top and cross-sectional views of a package in accordance with an embodiment of the disclosure.

FIG. 15 illustrates a cross-sectional view of a package in accordance with an embodiment of the disclosure.

FIGS. 16A, 16B and 16C illustrate top and cross-sectional views of a package in accordance with an embodiment of the disclosure.

FIG. 17 illustrates a cross-sectional view of a package in accordance with an embodiment of the disclosure.

FIG. 18 illustrates a cross-sectional view of a package in accordance with an embodiment of the disclosure.

FIGS. 19A and 19B illustrate cross-sectional views of a package in accordance with an embodiment of the disclosure.

FIG. 20 illustrates a cross-sectional view of a package in accordance with an embodiment of the disclosure.

FIGS. 21A, 21B and 21C illustrate top and cross-sectional views of a package in accordance with an embodiment of the disclosure.

FIG. 22 illustrates a cross-sectional view of a package in accordance with an embodiment of the disclosure.

FIG. 23 illustrates a cross-sectional view of a package in accordance with an embodiment of the disclosure.

FIGS. 24A and 24B illustrate cross-sectional views of a package in accordance with an embodiment of the disclosure.

FIG. 25 illustrates a cross-sectional view of a package in accordance with an embodiment of the disclosure.

FIGS. 26A, 26B and 26C illustrate top and cross-sectional views of a package in accordance with an embodiment of the disclosure.

FIG. 27 illustrates a cross-sectional view of a package in accordance with an embodiment of the disclosure.

FIG. 28 illustrates a cross-sectional view of a package in accordance with an embodiment of the disclosure.

FIGS. 29A and 29B illustrate cross-sectional views of a package in accordance with an embodiment of the disclosure.

FIG. 30 illustrates a cross-sectional view of a package in accordance with an embodiment of the disclosure.

FIGS. 31A and 31B illustrate top and cross-sectional views of a package in accordance with an embodiment of the disclosure.

FIGS. 32A, 32B and 32C illustrate top and cross-sectional views of a package in accordance with an embodiment of the disclosure.

FIG. 33 illustrates a cross-sectional view of a package in accordance with an embodiment of the disclosure.

FIG. 34 illustrates a cross-sectional view of a package in accordance with an embodiment of the disclosure.

FIG. 35 illustrates a cross-sectional view of a package in accordance with an embodiment of the disclosure.

FIGS. 36A, 36B and 36C illustrate top and cross-sectional views of a package in accordance with an embodiment of the disclosure.

FIGS. 37A and 37B illustrate top and cross-sectional views of a package in accordance with an embodiment of the disclosure.

FIG. 38 illustrates a cross-sectional view of a package in accordance with an embodiment of the disclosure.

FIG. 39 illustrates a cross-sectional view of a package in accordance with an embodiment of the disclosure.

FIGS. 40 and 41 illustrate cross-sectional views of package components in accordance with an embodiment of the disclosure.

FIG. 42 is a flow chart of a method of manufacturing a package in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, a package includes a substrate and package components bonded thereto. These package components may have various functions and may communicate with each other through the substrate. In certain embodiments, the package components are different types of semiconductor devices (referred to as different dies in some embodiments). Some embodiments feature package components that integrate a photonic integrated circuit (PIC) with an electronic integrated circuit (EIC). Additionally, some embodiments include package components that are logic devices and/or memory devices. The logic devices may include application-specific integrated circuit (ASIC) dies, central processing units (CPUs), graphics processing units (GPUs), system on chip (SoC) dies, microcontrollers, or the like. The memory devices may include hybrid memory cube (HMC) devices, high bandwidth memory (HBM) devices, or the like. In some embodiments, the logic and/or memory devices may be integrated into the same package component or exist as separate package components.

To prevent warpage of the package, a warpage control structure (referred to as a supporting structure in some embodiments) is attached to the substrate to reinforce the structure of the package and improve package coplanarity.

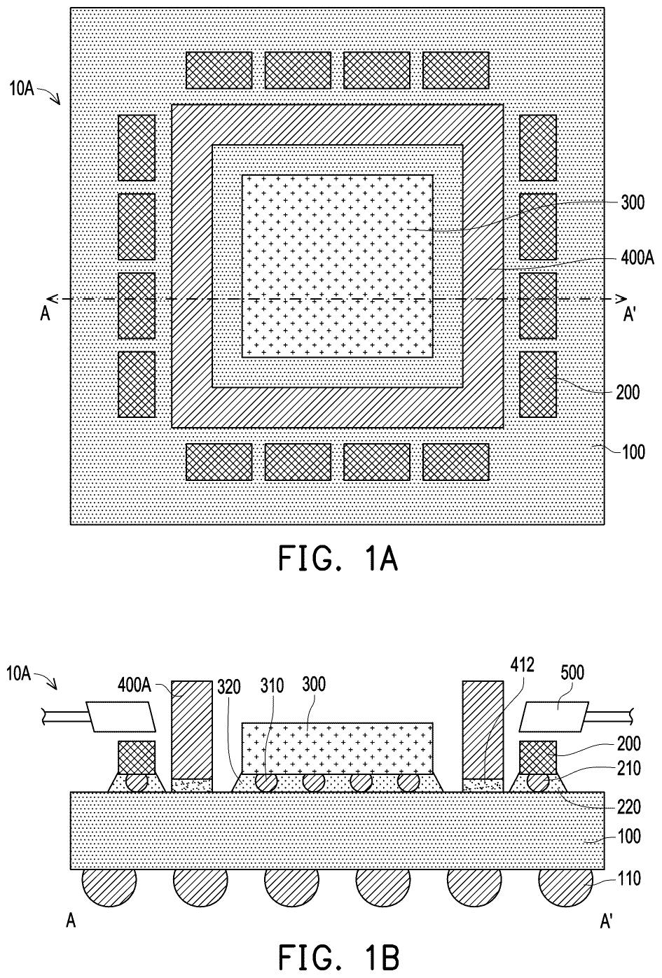

FIGS. 1A and 1B illustrate top and cross-sectional views of a package 10A in accordance with an embodiment of the disclosure. FIG. 1B is a cross-sectional view taken along a line A-A′ in FIG. 1A. Referring to FIGS. 1A and 1B, the package 10A includes a substrate 100, a first package component 300, a plurality of second package components 200, and a warpage control structure 400A. In some embodiments, the substrate 100 is a package substrate, which may include a semiconductor substrate core (such as silicon, germanium, diamond, silicon germanium, silicon carbide, gallium arsenic, indium arsenide, indium phosphide, silicon germanium carbide, gallium arsenic phosphide, gallium indium phosphide, combinations thereof, or the like), an insulating core (such as a fiberglass reinforced resin core), or the like. One example core material is fiberglass resin such as FR4. Alternatives for the core material include bismaleimide-triazine (BT) resin, or alternatively, other printed circuit board (PCB) materials or films.

The first package component 300 (referred to as the first semiconductor device or first die in some embodiments) and the second package components 200 (referred to as second semiconductor devices or second dies in some embodiments) are bonded to the substrate 100 by first connectors 310 and second connectors 210, respectively.

In some embodiments, the first connectors 310 and the second connectors 210 may be ball grid arrays (BGAs) comprising a eutectic material such as solder, although other suitable materials may also be used. Optionally, underbump metallization or additional metallization layers (not shown separately in FIG. 1B) may be utilized on the first connectors 310 and the second connectors 210. In some embodiments, the first connectors 310 and the second connectors 210 are solder bumps, lead-free solder bumps, or micro bumps, such as controlled collapse chip connection (C4) bumps or micro bumps containing copper pillars.

In some embodiments, a first underfill layer 320 is disposed between the substrate 100 and the first package component 300, and second underfill layers 220 are disposed between the substrate 100 and the second package components 200. The first underfill layer 320 and the second underfill layers 220 may reduce stress and protect the joints resulting from the reflowing of the first connectors 310 and the second connectors 210. The first underfill layer 320 and the second underfill layers 220 may be formed by a capillary flow process after the first package component 300 and the second package components 200 are attached.

The first package component 300 is situated above the central area of the substrate 100. The first package component 300 may include logic devices and/or memory devices. The logic devices may include ASIC dies, CPUs, GPUs, SoCs, microcontrollers, or similar devices. The memory devices may include HMC, HBM, or the like. In some embodiments, the logic and/or memory devices may be integrated into the same first package component 300 or exist as separate package components. In other words, while FIG. 1A shows one first package component 300, the package 10A may contain multiple first package components 300 disposed on the central area of the substrate 100 in other embodiments.

The second package components 200 are positioned above the peripheral area of the substrate 100, arranged around the first package component 300. Compared to the first package component 300, the second package components 200 are closer to the edge of the substrate 100. The second package components 200 are configured to receive optical signals from or transmit optical signals to optical fibers 500. In some embodiments, the optical fibers 500 may be a fiber array unit (FAU). For example, each second package component 200 may include a photonic integrated circuit (PIC) integrated with an electronic integrated circuit (EIC). The PIC comprises optical devices such as waveguides, modulators, splitters, optical couplers, or similar components. In some embodiments, each second package component 200 includes an optical coupler. The optical coupler may be a grating coupler or edge coupler. Photodiodes may be integrated within PIC or EIC. In some embodiments, the second package components 200 may be a compact universal photonic engine (COUPE).

The second package components 200 are electrically connected to the first package component 300 though the substrate 100. For example, optical signals are converted into electrical signals within the second package components 200. These electrical signals then pass through conductive structures (not shown) within the substrate 100 to reach the first package component 300.

The warpage control structure 400A (referred to as a supporting structure in some embodiments) is attached on the substrate 100 by a first adhesive layer 412. At least a portion of the warpage control structure 400A is laterally located between the first package component 300 and the second package components 200. In some embodiments, the warpage control structure 400A horizontally surrounds the first package component 300, creating a lateral separation between the first package component 300 and the second package components 200. The first adhesive layer 412 is positioned laterally between the first underfill layer 310 and the second underfill layers 420. The warpage control structure 400A is employed to manage or minimize warpage of the package 10A.

In some embodiments, the package 10A includes multiple first package components 300. In such cases, the warpage control structure 400A horizontally surrounds the multiple first package components 300.

In some embodiments, the material of the warpage control structure 400A includes metal (such as copper, stainless steel, etc.), semiconductor material (such as silicon), dielectric material, a combination thereof, or the like.

The conductive connectors 110, such as solder balls, are formed at the lower surface of the substrate 100.

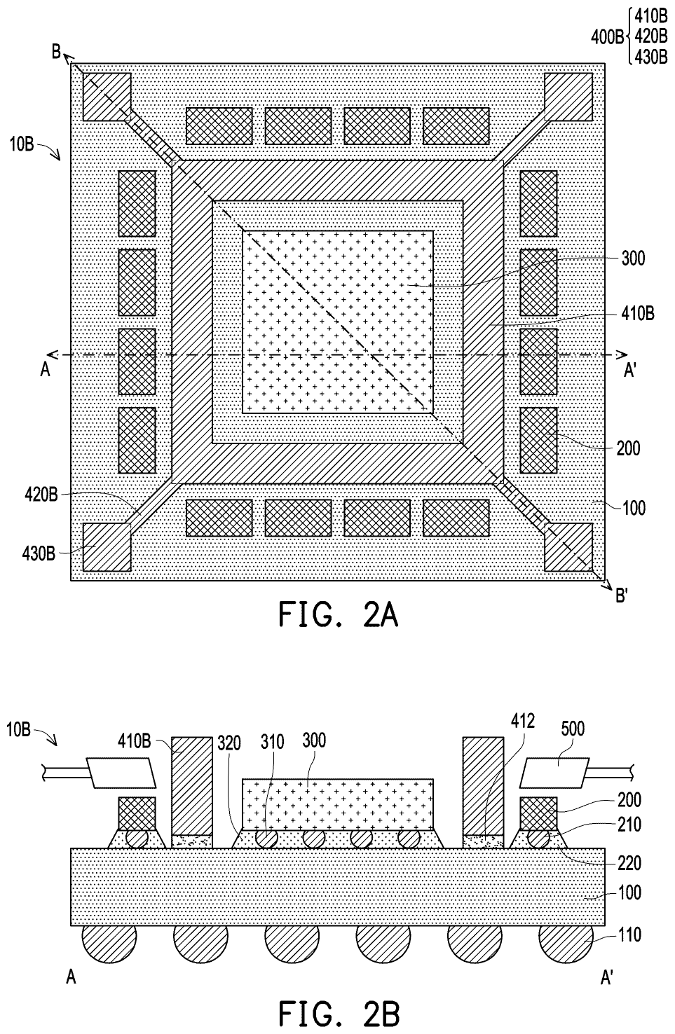

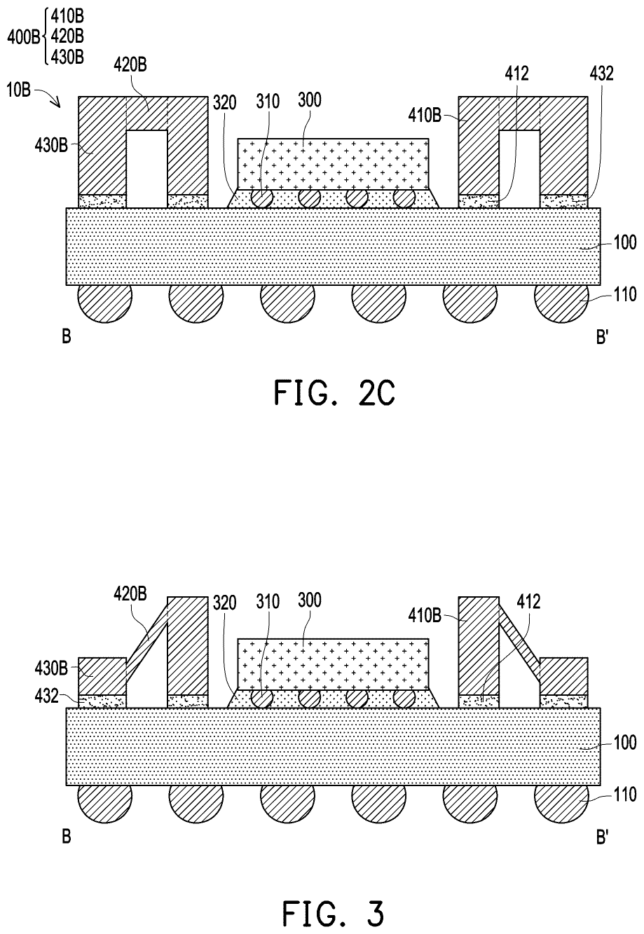

FIGS. 2A to 2C illustrate top and cross-sectional views of a package 10B in accordance with an embodiment of the disclosure. The package 10B in FIGS. 2A to 2C is similar to the package 10A in FIGS. 1A and 1B, with the difference being that in the package 10B, the warpage control structure 400B (referred to as a supporting structure in some embodiments) includes a wall portion 410B, a plurality of first connection portions 420B, and a plurality of block portions 430B.

Referring to FIGS. 2A to 2C, the wall portion 410B, the first connection portions 420B, and the block portions 430B are integrated to form the warpage control structure 400B. The wall portion 410B, the first connection portions 420B, and the block portions 430B are unified into a single structure.

The wall portion 410B surrounds the first package component 300, separating the first package component 300 from the second package components 200. The wall portion 410B is adhered to the substrate 100 by the first adhesive layer 412.

The block portions 430B are respectively disposed near the corners of the substrate 100. Typically, there is space without die placement at the corners of the substrate 100. In some embodiments, the space is utilized by placing the block portions 430B to increase the adhesive area between the warpage control structure 400B and the substrate 100, thereby enhancing the structural stability. The block portions 430B are adhered to the substrate 100 by second adhesive layers 432.

The first connection portions 420B are individually connected to the block portions 430B and extend from the block portions 430B toward the wall portion 410B. In some embodiments, the first connection portions 420B connect the block portions 430B to the wall portion 410B. In some embodiments, the width of each first connection portion 420B is narrower than the width of each block portion 430B.

FIGS. 2C to 5 depict schematic cross-sectional views of packages in different embodiments. The top views of the packages in FIGS. 2C to 5 correspond to FIG. 2A, and FIGS. 2C to 5 align with the position of line B-B′ in FIG. 2A.

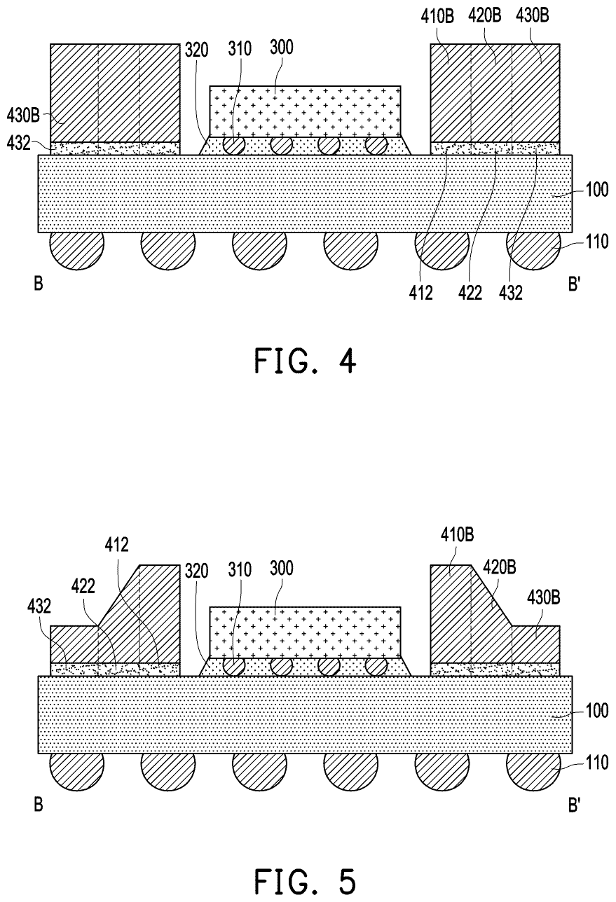

In some embodiments, the height of the wall portion 410B is equal to the height of the block portions 430B, and the top surfaces of the wall portion 410B, the first connection portions 420B, and the block portions 430B are in the same plane. In other words, the warpage control structure 400B has a flat top surface, as shown in FIGS. 2C and 4. In some embodiments, the height of the wall portion 410B differs (for example, is greater) from the height of the block portions 430B, and the first connection portions 420B have inclined top surfaces, as shown in FIGS. 3 and 5.

In some embodiments, gaps exist between the first connection portions 420B and the substrate 100, as shown in FIGS. 2C and 3. In other embodiments, the first connection portions 420B are adhered to the substrate 100 by third adhesive layers 422, as depicted in FIGS. 4 and 5.

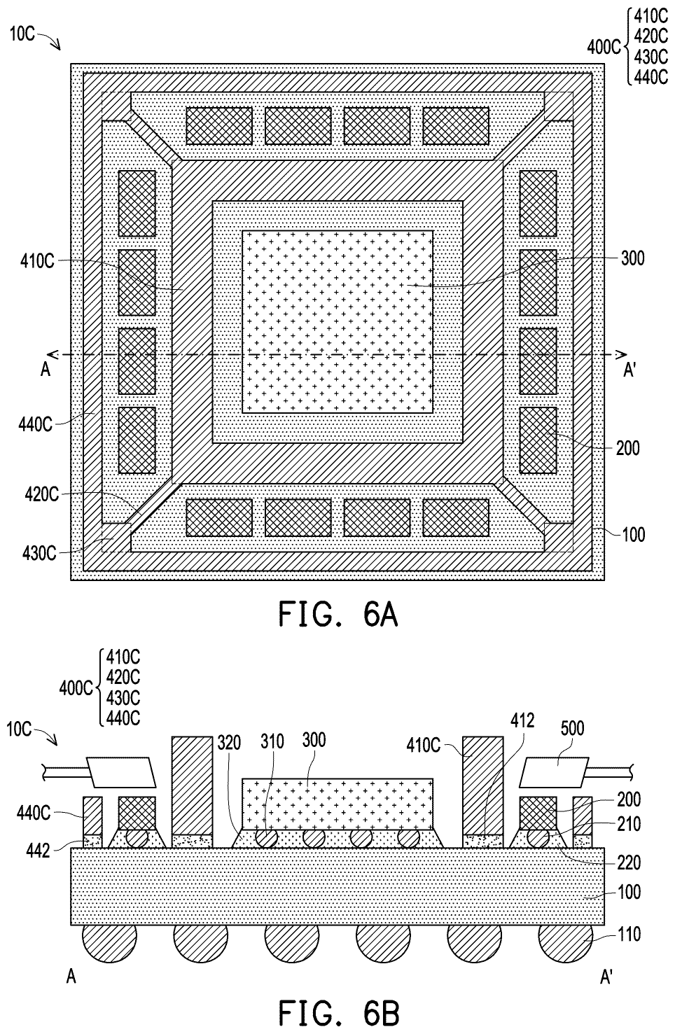

FIGS. 6A and 6B illustrate top and cross-sectional views of a package 10C in accordance with an embodiment of the disclosure. The package 10C in FIGS. 6A and 6B is similar to the package 10B in FIGS. 2A to 2C, with the difference being that in the package 10C, the warpage control structure 400C (referred to as a supporting structure in some embodiments) includes a wall portion 410C, a plurality of first connection portions 420C, a plurality of block portions 430C, and a ring portion 440C.

Referring to FIGS. 6A and 6B, the wall portion 410C, the first connection portions 420C, the block portions 430C, and the ring portion 440C are integrated to form the warpage control structure 400C. The wall portion 410C, the first connection portions 420C, the block portions 430C, and the ring portion 440C are unified into a single structure.

The wall portion 410C surrounds the first package component 300, separating the first package component 300 from the second package components 200. The wall portion 410C is adhered to the substrate 100 by the first adhesive layer 412.

The block portions 430C are respectively disposed near the corners of the substrate 100. The block portions 430C is used to increase the adhesive area between the warpage control structure 400C and the substrate 100, thereby enhancing the structural stability. The block portions 430C are adhered to the substrate 100 by the second adhesive layers.

The first connection portions 420C are individually connected to the block portions 430C and extend from the block portions 430C toward the wall portion 410C. In some embodiments, the first connection portions 420C connect the block portions 430C to the wall portion 410C. In some embodiments, the width of each first connection portion 420C is narrower than the width of each block portion 430C.

In some embodiments, the cross-sectional structures of the block portions 430C and the first connection portions 420C may be the same as the block portions 430B and the first connection portions 420B shown in FIGS. 2C to 5.

The ring portion 440C is connected to the block portions 430C. The ring portion 440C is near the edge of the substrate 100, and the second package components 200 are located between the ring portion 440C and the wall portion 410C. The ring portion 440C is attached to the substrate 100 by a fourth adhesive layer 442.

In some embodiments, the height of the ring portion 440C is less than or equal to the height of the second package components 200, thereby reducing interference from the ring portion 440C with the optical fibers 500. In some embodiments, a receptacle is placed on the ring portion 440C or between the ring portion 440C and the edge of the substrate 100, which is used for connecting the optical fibers 500.

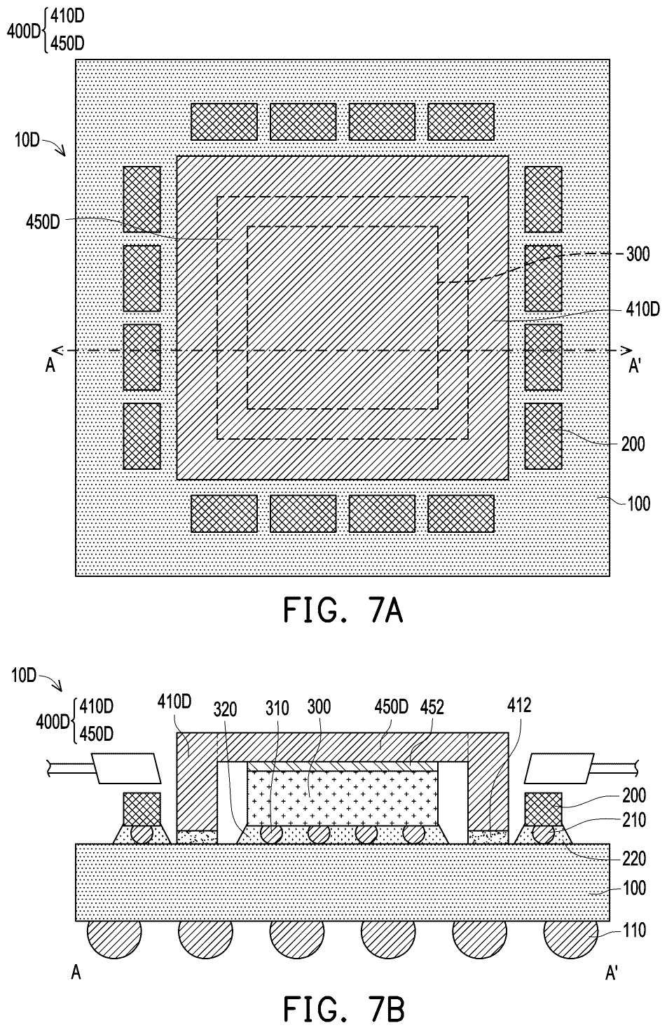

FIGS. 7A and 7B illustrate top and cross-sectional views of a package 10D in accordance with an embodiment of the disclosure. The package 10D in FIGS. 7A and 7B is similar to the package 10A in FIGS. 1A and 1B, with the difference being that in the package 10D, the warpage control structure 400D (referred to as a supporting structure in some embodiments) includes a wall portion 410D and a lid portion 450D.

Referring to FIGS. 7A and 7B, the wall portion 410D and the lid portion 450D are integrated to form the warpage control structure 400D. The wall portion 410D and the lid portion 450D are unified into a single structure.

The wall portion 410D surrounds the first package component 300, separating the first package component 300 from the second package components 200. The wall portion 410D is adhered to the substrate 100 by the first adhesive layer 412.

The lid portion 450D is connected to the wall portion 410D. The lid portion 450D is disposed above the first package component 300, and a first thermal interface material (TIM) layer 452 is located between the lid portion 450D and the first package component 300. In some embodiments, the first TIM layer 452 and the first adhesive layer 412 comprise different materials. For example, the thermal conductivity of the first TIM layer 452 is higher than that of the first adhesive layer 412, thereby effectively improving the heat dissipation of the first package component 300.

The first TIM layer 452 may include, for example, a gel TIM, graphite TIM, metal TIM, solder TIM, or carbon nanotube TIM. Other types of TIMs are within the contemplated scope of this disclosure. In some embodiments, the first TIM layer 452 may be formed on the first package component 300 to dissipate heat generated during the operation of the package 10D. The first TIM layer 452 may be attached to the first package component 300, for example, by a thermally conductive adhesive. In particular, the first TIM layer 452 may contact an upper surface of the first package component 300.

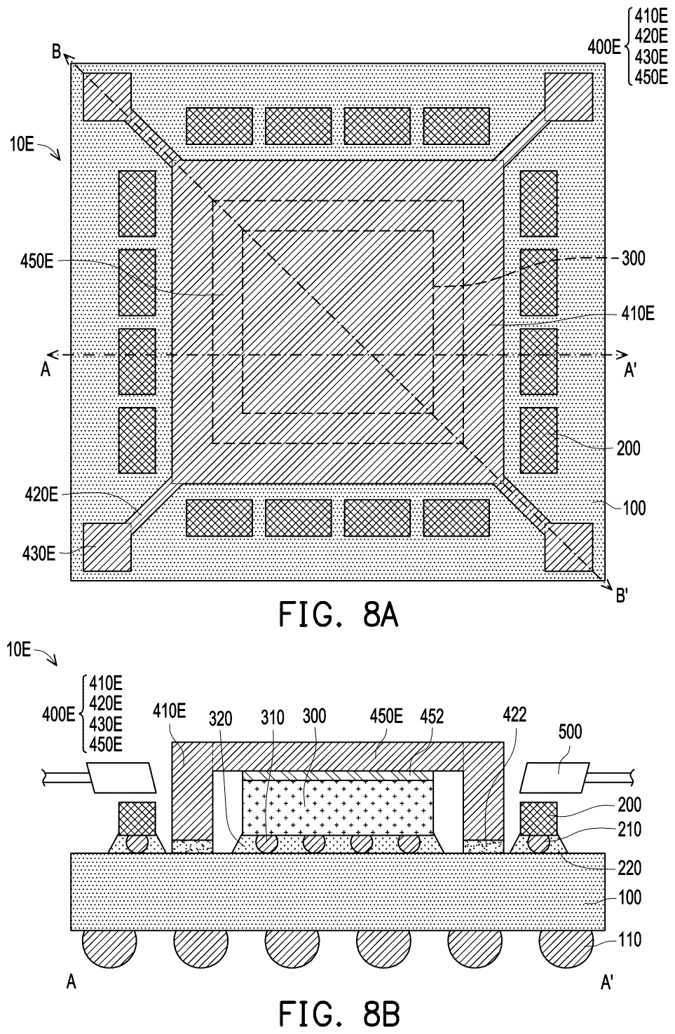

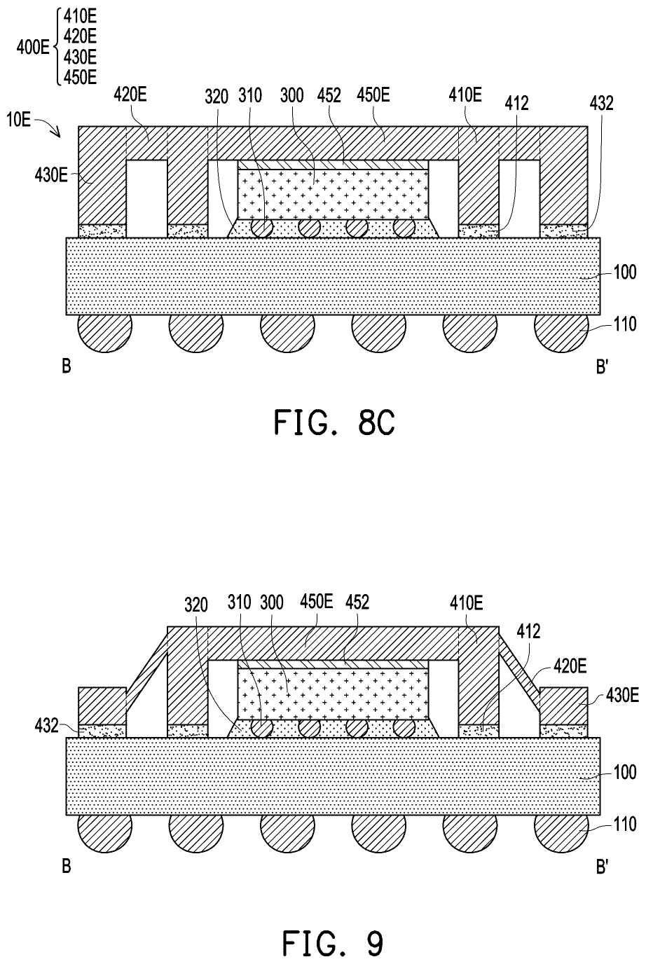

FIGS. 8A to 8C illustrate top and cross-sectional views of a package 10E in accordance with an embodiment of the disclosure. The package 10E in FIGS. 8A to 8C is similar to the package 10D in FIGS. 7A and 7B, with the difference being that in the package 10E, the warpage control structure 400E (referred to as a supporting structure in some embodiments) includes a wall portion 410E, a plurality of first connection portions 420E, a plurality of block portions 430E, and a lid portion 450E.

Referring to FIGS. 8A to 8C, the wall portion 410E, the first connection portions 420E, the block portions 430E, and the lid portion 450E are integrated to form the warpage control structure 400E. The wall portion 410E, the first connection portions 420E, the block portions 430E, and the lid portion 450E are unified into a single structure.

The wall portion 410E surrounds the first package component 300, separating the first package component 300 from the second package components 200. The wall portion 410E is adhered to the substrate 100 by the first adhesive layer 412.

The block portions 430E are respectively disposed near the corners of the substrate 100. The block portions 430E is used to increase the adhesive area between the warpage control structure 400E and the substrate 100, thereby enhancing the structural stability. The block portions 430E are adhered to the substrate 100 by second adhesive layers 432.

The first connection portions 420E are individually connected to the block portions 430E and extend from the block portions 430E toward the wall portion 410E. In some embodiments, the first connection portions 420E connect the block portions 430E to the wall portion 410E. In some embodiments, the width of each first connection portion 420E is narrower than the width of each block portion 430E.

The lid portion 450E is connected to the wall portion 410E. The lid portion 450E is disposed above the first package component 300, and the first TIM layer 452 is located between the lid portion 450E and the first package component 300.

FIGS. 8C to 11 depict schematic cross-sectional views of packages in different embodiments. The top views of the packages in FIGS. 8C to 11 correspond to FIG. 8A, and FIGS. 8C to 11 align with the position of line B-B′ in FIG. 8A.

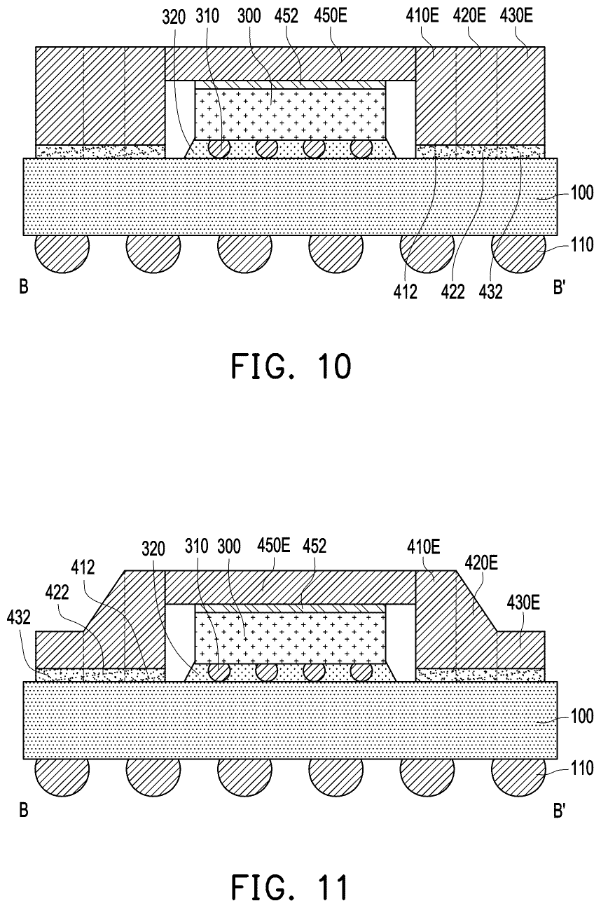

In some embodiments, the height of the wall portion 410E is equal to the height of the block portions 430E, and the top surfaces of the wall portion 410E, the first connection portions 420E, and the block portions 430E are in the same plane. In other words, the warpage control structure 400E has a flat top surface, as shown in FIGS. 8C and 10. In some embodiments, the height of the wall portion 410E differs (for example, is greater) from the height of the block portions 430E, and the first connection portions 420E have inclined top surfaces, as shown in FIGS. 9 and 11.

In some embodiments, gaps exist between the first connection portions 420E and the substrate 100, as shown in FIGS. 8C and 9. In other embodiments, the first connection portions 420E are adhered to the substrate 100 by the third adhesive layers 422, as depicted in FIGS. 10 and 11.

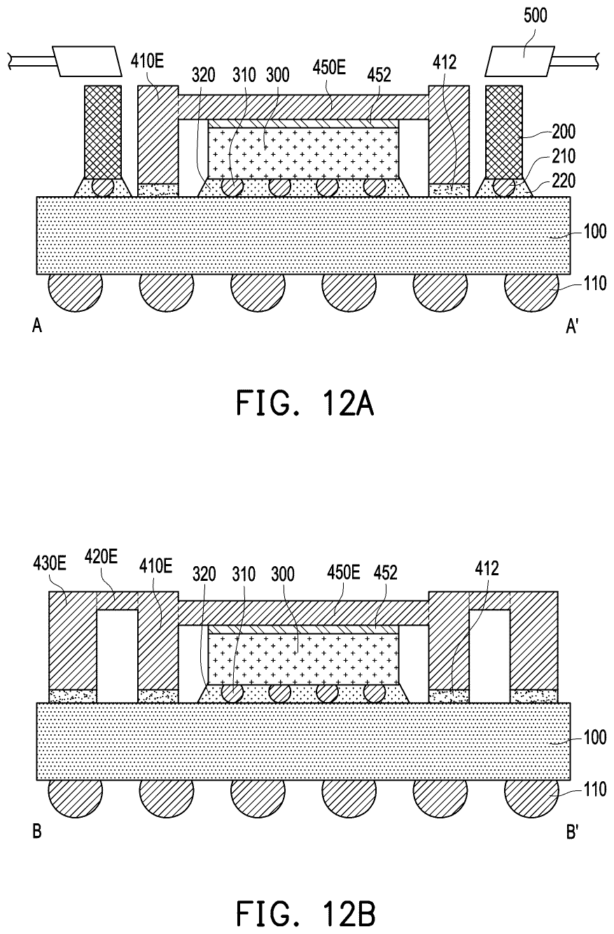

FIGS. 12A and 12B depict schematic cross-sectional views of a package in another embodiment. The top views of the packages in FIGS. 12A and 12B correspond to FIG. 8A, with FIGS. 12A and 12B aligning with the positions of line A-A′ and line B-B′ in FIG. 8A, respectively.

The package in FIGS. 12A and 12B is similar to the package 10E in FIGS. 8A to 8C, with the difference being that in FIGS. 12A and 12B, the height of the second package components 200 is greater than that of the first package component 300, and the top surfaces of the wall portion 410E, the first connection portions 420E and the block portions 430E are higher than the top surface of the lid portion 450E.

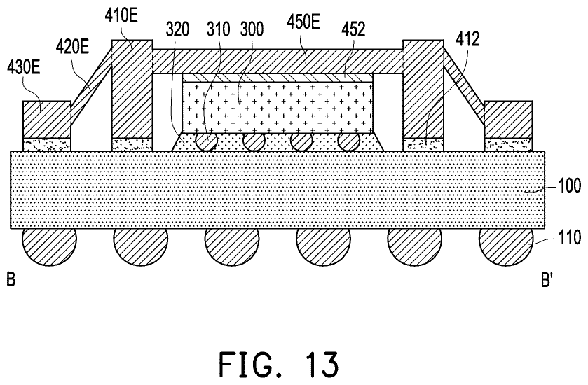

In FIG. 12B, the height of the block portions 430E is the same as the height of the wall portion 410E, but this disclosure is not limited thereto. In other embodiments, the height of the block portions 430E is different (e.g., lower) than the height of the wall portion 410E, as shown in FIG. 13.

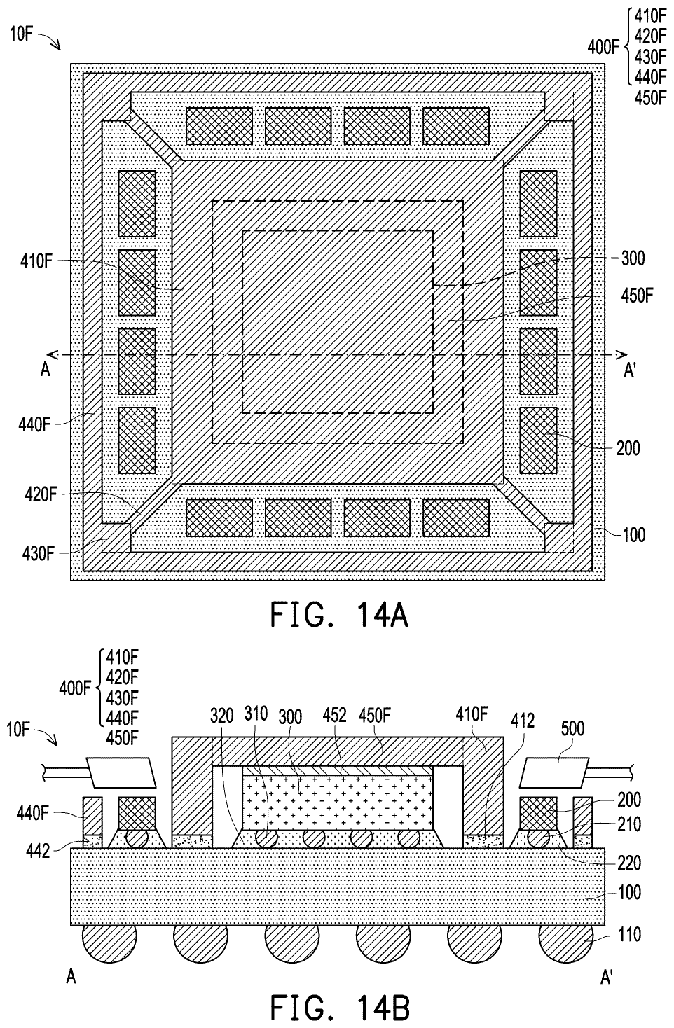

FIGS. 14A and 14B illustrate top and cross-sectional views of a package 10F in accordance with an embodiment of the disclosure. The package 10F in FIGS. 14A and 14B is similar to the package 10E in FIGS. 8A to 8C, with the difference being that in the package 10F, the warpage control structure 400F (referred to as a supporting structure in some embodiments) includes a wall portion 410F, a plurality of first connection portions 420F, a plurality of block portions 430F, a ring portion 440F, and a lid portion 450F.

Referring to FIGS. 14A and 14B, the wall portion 410F, the first connection portions 420F, the block portions 430F, the ring portion 440F, and the lid portion 450F are integrated to form the warpage control structure 400F. The wall portion 410F, the first connection portions 420F, the block portions 430F, the ring portion 440F, and the lid portion 450F are unified into a single structure.

The wall portion 410F surrounds the first package component 300, separating the first package component 300 from the second package components 200. The wall portion 410F is adhered to the substrate 100 by the first adhesive layer 412.

The block portions 430F are respectively disposed near the corners of the substrate 100. The block portions 430F is used to increase the adhesive area between the warpage control structure 400F and the substrate 100, thereby enhancing the structural stability. The block portions 430F are adhered to the substrate 100 by the second adhesive layers.

The first connection portions 420F are individually connected to the block portions 430F and extend from the block portions 430F toward the wall portion 410F. In some embodiments, the first connection portions 420F connect the block portions 430F to the wall portion 410F. In some embodiments, the width of each first connection portion 420F is narrower than the width of each block portion 430F.

In some embodiments, the cross-sectional structures of the block portions 430F and the first connection portions 420F may be the same as the block portions 430E and the first connection portions 420E shown in FIGS. 8C to 11.

The lid portion 450F is connected to the wall portion 410F. The lid portion 450F is disposed above the first package component 300, and the first TIM layer 452 is located between the lid portion 450F and the first package component 300.

The ring portion 440F is connected to the block portions 430F. The ring portion 440F is near the edge of the substrate 100, and the second package components 200 are located between the ring portion 440F and the wall portion 410F. The ring portion 440F is attached to the substrate 100 by the fourth adhesive layer 442.

In some embodiments, the height of the ring portion 440F is less than or equal to the height of the second package components 200, thereby reducing interference from the ring portion 440F with the optical fibers 500. In some embodiments, a receptacle is placed on the ring portion 440F or between the ring portion 440F and the edge of the substrate 100, which is used for connecting the optical fibers 500.

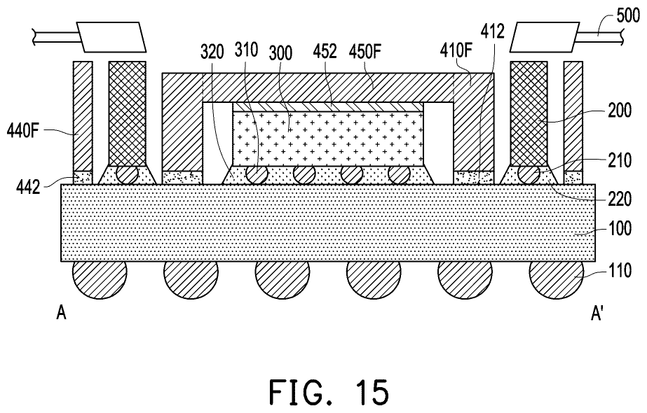

In FIG. 14B, the height of the second package components 200 is less than the height of the first package component 300, but the disclosure is not limited thereto. In other embodiments, the height of the second package components 200 is greater than the height of the first package component 300, as shown in FIG. 15.

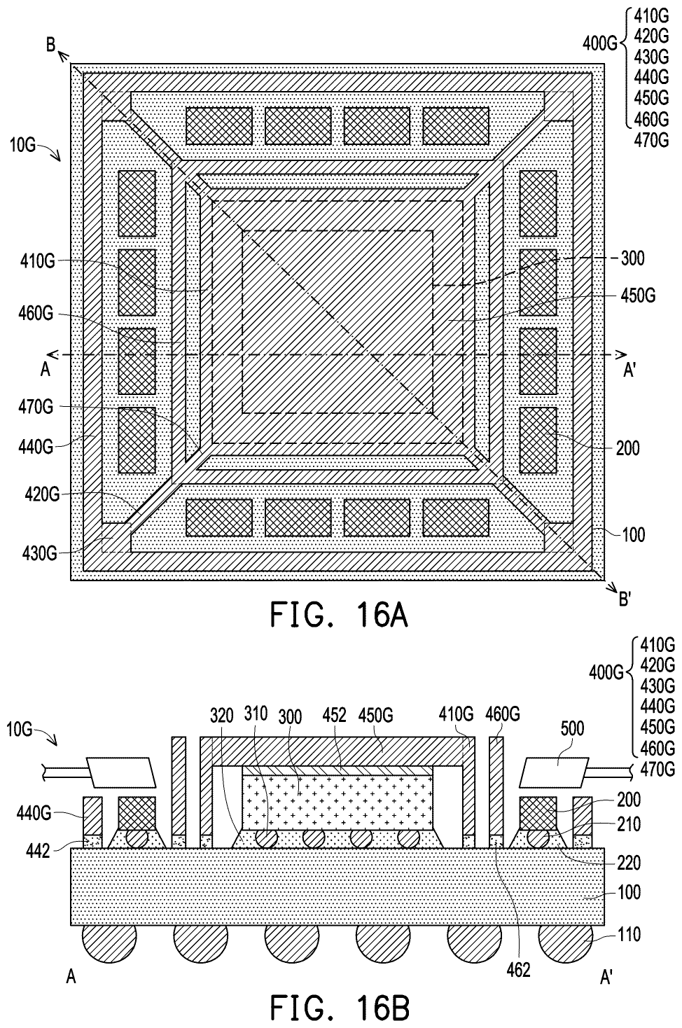

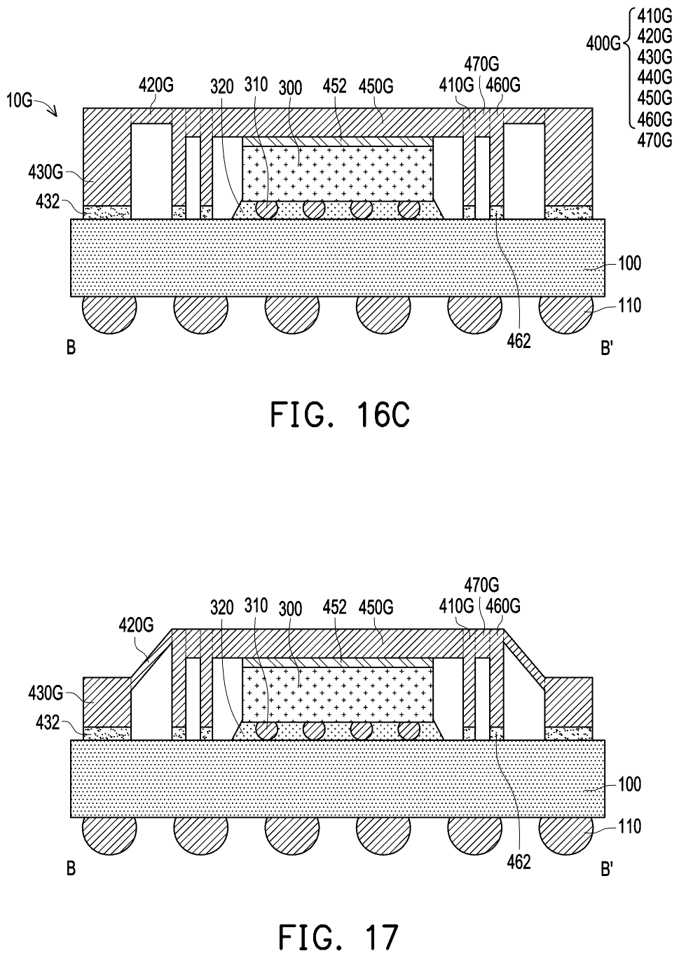

FIGS. 16A to 16C illustrate top and cross-sectional views of a package 10G in accordance with an embodiment of the disclosure. The package 10G in FIGS. 16A to 16C is similar to the package 10F in FIGS. 14A and 14B, with the difference being that in the package 10G, the warpage control structure 400G (referred to as a supporting structure in some embodiments) includes a wall portion 410G, a plurality of first connection portions 420G, a plurality of block portions 430G, a ring portion 440G, a lid portion 450G, an extension portion 460G, and a plurality of second connection portions 470G.

Referring to FIGS. 16A to 16C, the wall portion 410G, the first connection portions 420G, the block portions 430G, the ring portion 440G, the lid portion 450G, the extension portion 460G, and the second connection portions 470G are integrated to form the warpage control structure 400G. The wall portion 410G, the first connection portions 420G, the block portions 430G, the ring portion 440G, the lid portion 450G, the extension portion 460G, and the second connection portions 470G are unified into a single structure.

The wall portion 410G surrounds the first package component 300, separating the first package component 300 from the second package components 200. The wall portion 410G is adhered to the substrate 100 by the first adhesive layer 412.

The extension portion 460G surrounds the wall portion 410G, and a gap is located between the extension portion 460G and the wall portion 410G. The extension portion 460G is adhered to the substrate 100 by the fifth adhesive layer 462.

The block portions 430G are respectively disposed near the corners of the substrate 100. The block portions 430G is used to increase the adhesive area between the warpage control structure 400G and the substrate 100, thereby enhancing the structural stability. The block portions 430G are adhered to the substrate 100 by the second adhesive layers 432.

The first connection portions 420G are individually connected to the block portions 430G and extend from the block portions 430G toward the wall portion 410G. In some embodiments, the first connection portions 420G connect the block portions 430G to the extension portion 460G. In some embodiments, the width of each first connection portion 420G is narrower than the width of each block portion 430G.

The second connection portions 470G are connected to the extension portion 460G and extend from the extension portion 460G toward the wall portion 410G. In some embodiments, the second connection portions 470G connect the extension portion 460G to the wall portion 410G.

The lid portion 450G is connected to the wall portion 410G. The lid portion 450G is disposed above the first package component 300, and the first TIM layer 452 is located between the lid portion 450G and the first package component 300.

The ring portion 440G is connected to the block portions 430G. The ring portion 440G is near the edge of the substrate 100, and the second package components 200 are located between the ring portion 440G and the extension portion 460G. The ring portion 440G is attached to the substrate 100 by the fourth adhesive layer 442.

FIGS. 16C to 18 depict schematic cross-sectional views of packages in different embodiments. The top views of the packages in FIGS. 16C to 18 correspond to FIG. 16A, and FIGS. 16C to 18 align with the position of line B-B′ in FIG. 16A.

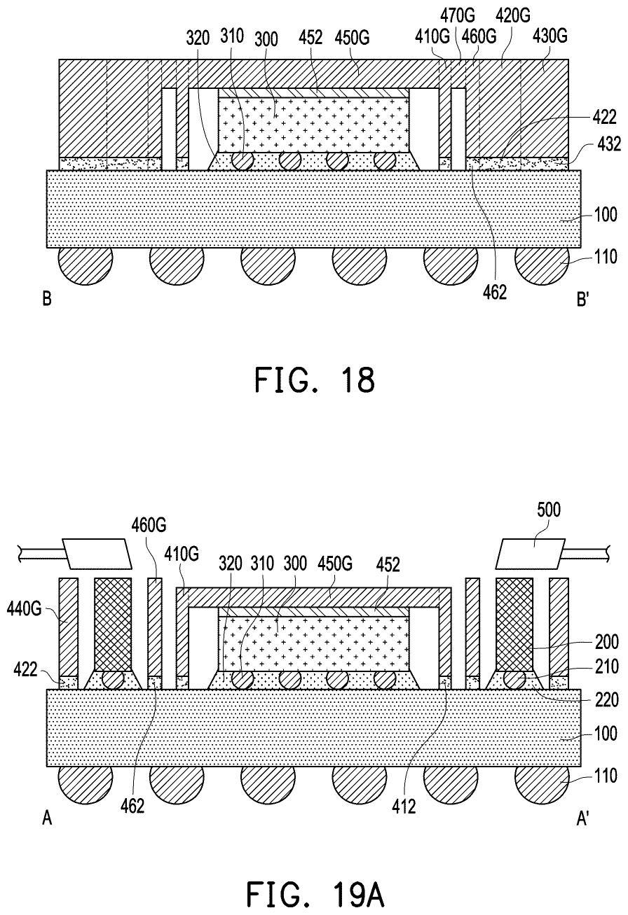

In some embodiments, the height of the wall portion 410G and the extension portion 460G is equal to the height of the block portions 430G, and the top surfaces of the wall portion 410G, the first connection portions 420G, the block portions 430G, the lid portion 450G, the extension portion 460G, and the second connection portions 470G are in the same plane. In other words, the warpage control structure 400G has a flat top surface, as shown in FIGS. 16C and 18. In some embodiments, the height of the wall portion 410G and the extension portion 460G differs (for example, is greater) from the height of the block portions 430G, and the first connection portions 420G have inclined top surfaces, as shown in FIG. 17.

In some embodiments, gaps exist between the first connection portions 420G and the substrate 100, as shown in FIGS. 16C and 17. In other embodiments, the first connection portions 420G are adhered to the substrate 100 by the third adhesive layers 422, as depicted in FIG. 18.

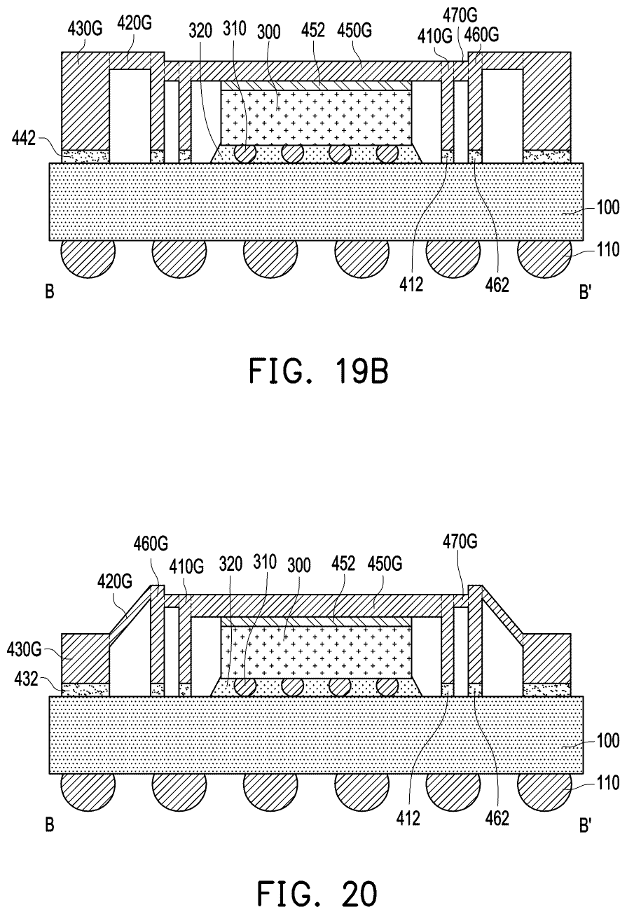

FIGS. 19A and 19B depict schematic cross-sectional views of a package in another embodiment. The top views of the packages in FIGS. 19A and 19B correspond to FIG. 16A, with FIGS. 19A and 19B aligning with the positions of line A-A′ and line B-B′ in FIG. 16A, respectively.

The package in FIGS. 19A and 19B is similar to the package 10G in FIGS. 16A to 16C, with the difference being that in FIGS. 19A and 19B, the height of the second package components 200 is greater than that of the first package component 300, and the top surfaces of the extension portion 460G, the first connection portions 420G and the block portions 430G are higher than the top surfaces of the lid portion 450G, the wall portion 410G, and the second connection portions 470G.

In FIG. 19B, the height of the block portions 430G is the same as the height of the extension portion 460G, but this disclosure is not limited thereto. In other embodiments, the height of the block portions 430G is different (e.g., lower) than the height of the extension portion 460G, as shown in FIG. 20.

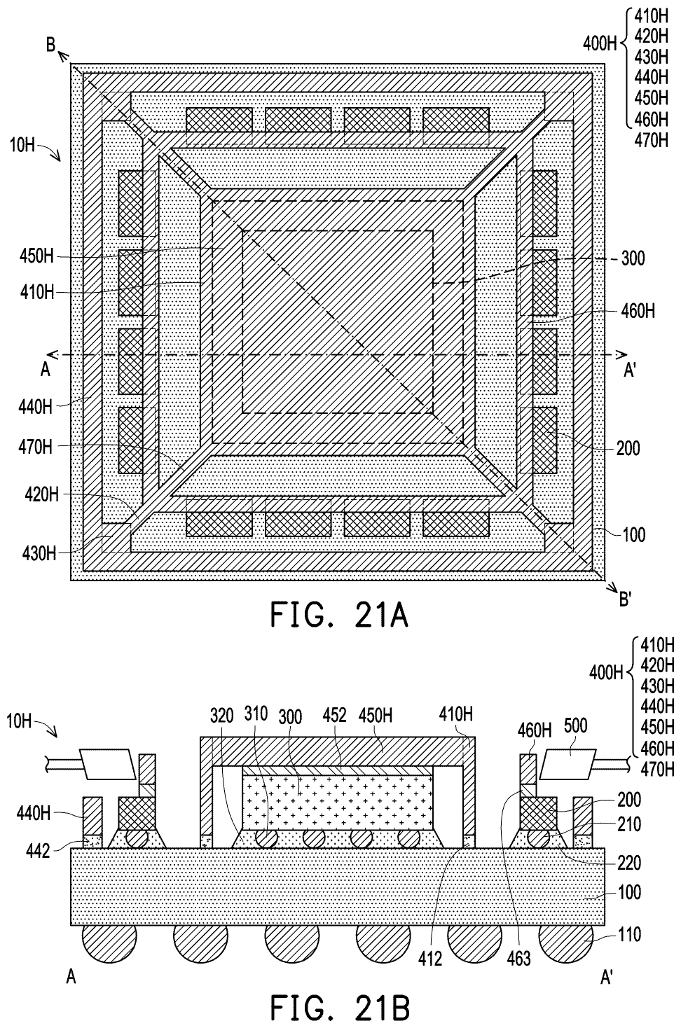

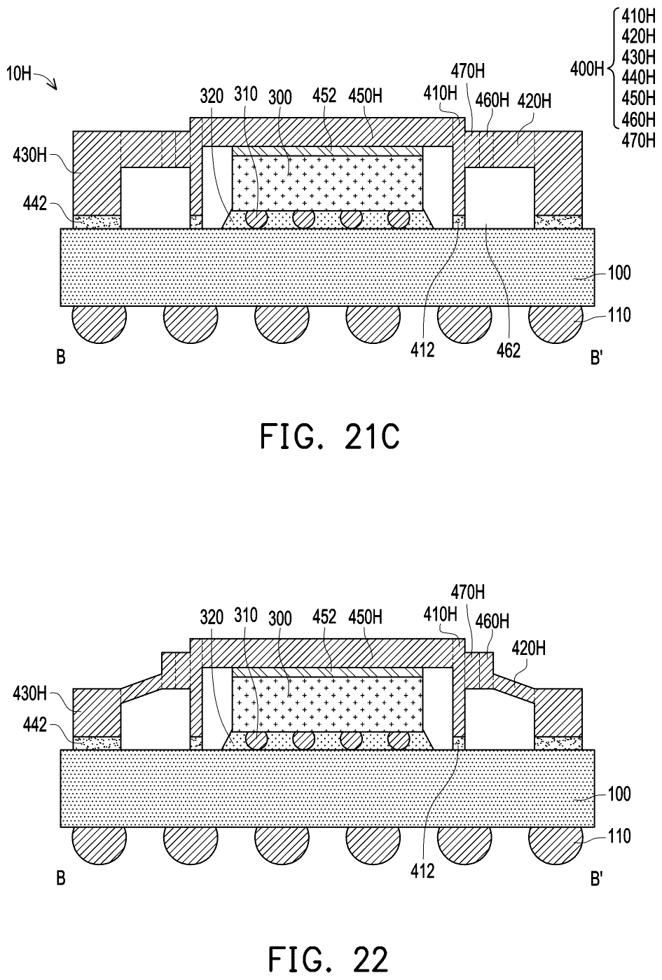

FIGS. 21A to 21C illustrate top and cross-sectional views of a package 10H in accordance with an embodiment of the disclosure. The package 10H in FIGS. 21A to 21C is similar to the package 10G in FIGS. 16A to 16C, with the difference being that in the package 10H, the warpage control structure 400H (referred to as a supporting structure in some embodiments) includes a wall portion 410H, a plurality of first connection portions 420H, a plurality of block portions 430H, a ring portion 440H, a lid portion 450H, an extension portion 460H, and a plurality of second connection portions 470H.

Referring to FIGS. 21A to 21C, the wall portion 410H, the first connection portions 420H, the block portions 430H, the ring portion 440H, the lid portion 450H, the extension portion 460H, and the second connection portions 470H are integrated to form the warpage control structure 400H. The wall portion 410H, the first connection portions 420H, the block portions 430H, the ring portion 440H, the lid portion 450H, the extension portion 460H, and the second connection portions 470H are unified into a single structure.

The wall portion 410H surrounds the first package component 300, separating the first package component 300 from the second package components 200. The wall portion 410H is adhered to the substrate 100 by the first adhesive layer 412.

The extension portion 460H surrounds the wall portion 410H, and a gap is located between the extension portion 460H and the wall portion 410H. The extension portion 460H is disposed above the second package components 200, and a plurality of second TIM layers 463 are disposed between the extension portion 460H and the second package components 200.

In some embodiments, the second TIM layers 463 and the first adhesive layer 412 comprise different materials. For example, the thermal conductivity of the second TIM layers 463 is higher than that of the first adhesive layer 412, thereby effectively improving the heat dissipation of the second package components 200.

The second TIM layers 463 may include, for example, a gel TIM, graphite TIM, metal TIM, solder TIM, or carbon nanotube TIM. Other types of TIMs are within the contemplated scope of this disclosure. In some embodiments, the second TIM layers 463 may be formed on the second package components 200 to dissipate heat generated during the operation of the package 10H. The second TIM layers 463 may be attached to the second package components 200, for example, by a thermally conductive adhesive. In particular, the second TIM layers 463 may contact upper surfaces of the second package components 200.

The block portions 430H are respectively disposed near the corners of the substrate 100. The block portions 430H is used to increase the adhesive area between the warpage control structure 400H and the substrate 100, thereby enhancing the structural stability. The block portions 430H are adhered to the substrate 100 by second adhesive layers 432.

The first connection portions 420H are individually connected to the block portions 430H and extend from the block portions 430H toward the wall portion 410H. In some embodiments, the first connection portions 420H connect the block portions 430H to the extension portion 460H. In some embodiments, the width of each first connection portion 420H is narrower than the width of each block portion 430H.

The second connection portions 470H are connected to the extension portion 460H and extend from the extension portion 460H toward the wall portion 410H. In some embodiments, the second connection portions 470H connect the extension portion 460H to the wall portion 410H.

The lid portion 450H is connected to the wall portion 410H. The lid portion 450H is disposed above the first package component 300, and the first TIM layer 452 is located between the lid portion 450H and the first package component 300.

The ring portion 440H is connected to the block portions 430H. The ring portion 440H is near the edge of the substrate 100, and the second package components 200 are located between the ring portion 440H and the wall portion 410H. The ring portion 440H is attached to the substrate 100 by the fourth adhesive layer 442.

FIGS. 21C to 23 depict schematic cross-sectional views of packages in different embodiments. The top views of the packages in FIGS. 21C to 23 correspond to FIG. 21A, and FIGS. 21C to 23 align with the position of line B-B′ in FIG. 21A.

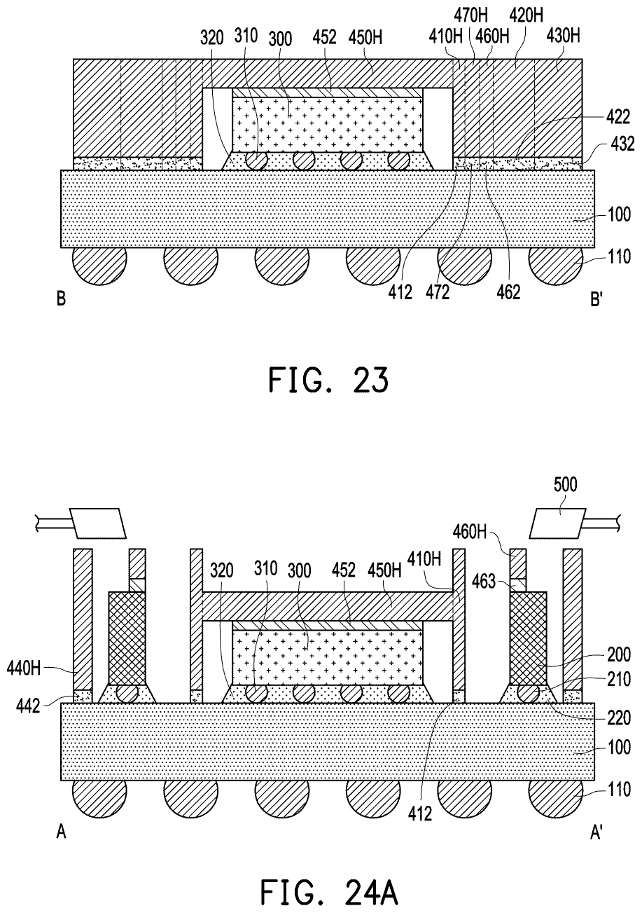

In some embodiments, the height of the wall portion 410H differs (for example, is greater) from the height of the block portions 430H, as shown in FIGS. 21C and 22. In some embodiments, the first connection portions 420H have inclined top surfaces, as shown in FIG. 22. In some embodiments, the height of the wall portion 410H is equal to the height of the block portions 430H, and the top surfaces of the wall portion 410H, the first connection portions 420H, the block portions 430H, the lid portion 450H, the extension portion 460H, and the second connection portions 470H are in the same plane. In other words, the warpage control structure 400H has a flat top surface, as shown in FIG. 23.

In some embodiments, gaps exist between the first connection portions 420H and the substrate 100, between the second connection portions 470H and the substrate 100 and between the extension portion 460H and the substrate 100, as shown in FIGS. 21C and 22. In other embodiments, the first connection portions 420H are adhered to the substrate 100 by third adhesive layers 422, the second connection portions 470H are adhered to the substrate 100 by the sixth adhesive layers 472, and the extension portion 460H is adhered to the substrate 100 by a seventh adhesive layers 462, as depicted in FIG. 23.

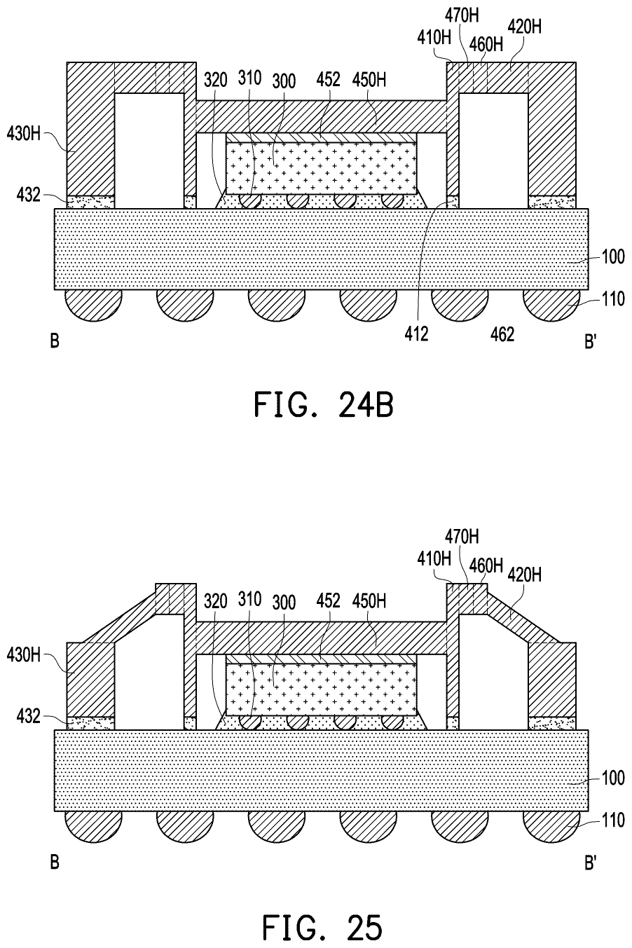

FIGS. 24A and 24B depict schematic cross-sectional views of a package in another embodiment. The top views of the packages in FIGS. 24A and 24B correspond to FIG. 21A, with FIGS. 24A and 24B aligning with the positions of line A-A′ and line B-B′ in FIG. 21A, respectively.

The package in FIGS. 24A and 24B is similar to the package 10H in FIGS. 21A to 21C, with the difference being that in FIGS. 24A and 24B, the height of the second package components 200 is greater than that of the first package component 300, and the top surfaces of the wall portion 410H, the first connection portions 420H, the block portions 430H, the extension portion 460H, and the second connection portions 470H are higher than the top surface of the lid portion 450H.

In FIG. 24B, the height of the block portions 430H is the same as the height of the wall portion 410H, but this disclosure is not limited thereto. In other embodiments, the height of the block portions 430H is different (e.g., lower) than the height of the wall portion 460H, as shown in FIG. 25.

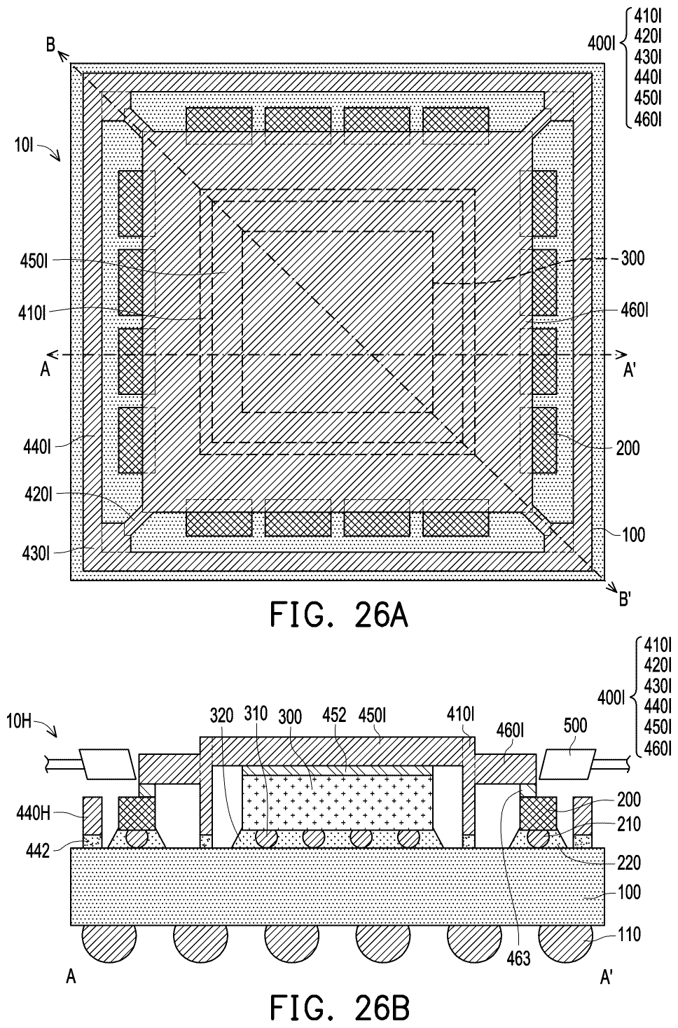

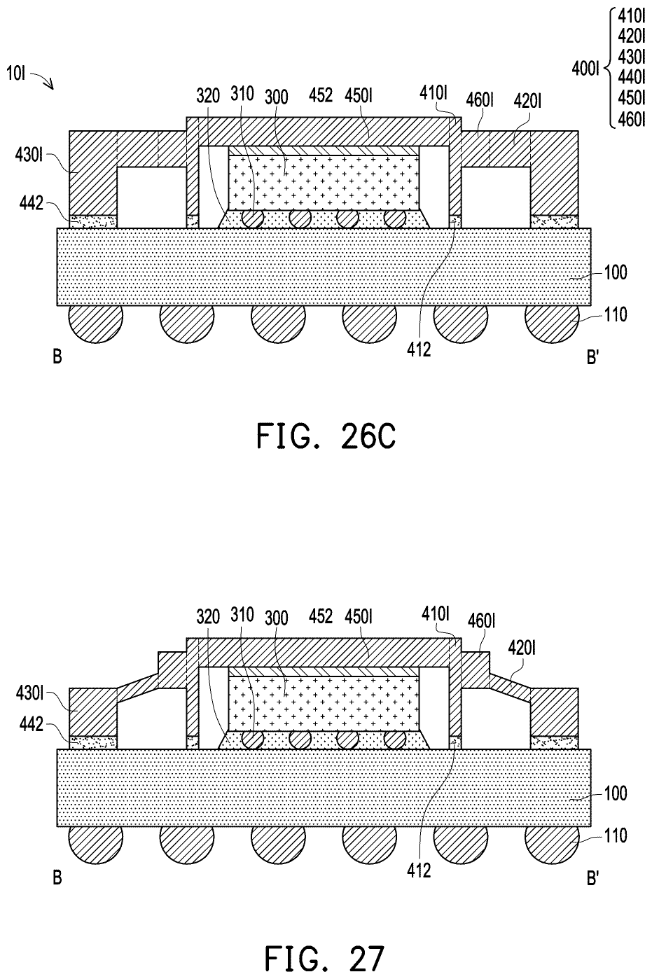

FIGS. 26A to 26C illustrate top and cross-sectional views of a package 10I in accordance with an embodiment of the disclosure. The package 10I in FIGS. 26A to 26C is similar to the package 10H in FIGS. 21A to 21C, with the difference being that in the package 10I, the warpage control structure 400I (referred to as a supporting structure in some embodiments) includes a wall portion 410I, a plurality of first connection portions 420I, a plurality of block portions 430I, a ring portion 440I, a lid portion 450I, and an extension portion 460I.

Referring to FIGS. 26A to 26C, the wall portion 410I, the first connection portions 420I, the block portions 430I, the ring portion 440I, the lid portion 450I, and the extension portion 460I are integrated to form the warpage control structure 400I. The wall portion 410I, the first connection portions 420I, the block portions 430I, the ring portion 440I, the lid portion 450I, and the extension portion 460I are unified into a single structure.

The wall portion 410I surrounds the first package component 300, separating the first package component 300 from the second package components 200. The wall portion 410I is adhered to the substrate 100 by the first adhesive layer 412.

The extension portion 460I is connected to the wall portion 410I and extends outward from the outer side wall of the wall portion 410I. The extension portion 460I is disposed above the second package components 200, and a plurality of second TIM layers 463 are disposed between the extension portion 460I and the second package components 200.

The block portions 430I are respectively disposed near the corners of the substrate 100. The block portions 430I is used to increase the adhesive area between the warpage control structure 400I and the substrate 100, thereby enhancing the structural stability. The block portions 430I are adhered to the substrate 100 by second adhesive layers 432.

The first connection portions 420I are individually connected to the block portions 430I and extend from the block portions 430I toward the wall portion 410I. In some embodiments, the first connection portions 420I connect the block portions 430I to the extension portion 460I. In some embodiments, the width of each first connection portion 420I is narrower than the width of each block portion 430I.

The lid portion 450I is connected to the wall portion 410I. The lid portion 450I is disposed above the first package component 300, and the first TIM layer 452 is located between the lid portion 450I and the first package component 300.

The ring portion 440I is connected to the block portions 430I. The ring portion 440I is near the edge of the substrate 100, and the second package components 200 are located between the ring portion 440I and the wall portion 410I. The ring portion 440I is attached to the substrate 100 by the fourth adhesive layer 442.

FIGS. 26C to 28 depict schematic cross-sectional views of packages in different embodiments. The top views of the packages in FIGS. 26C to 28 correspond to FIG. 26A, and FIGS. 26C to 28 align with the position of line B-B′ in FIG. 26A.

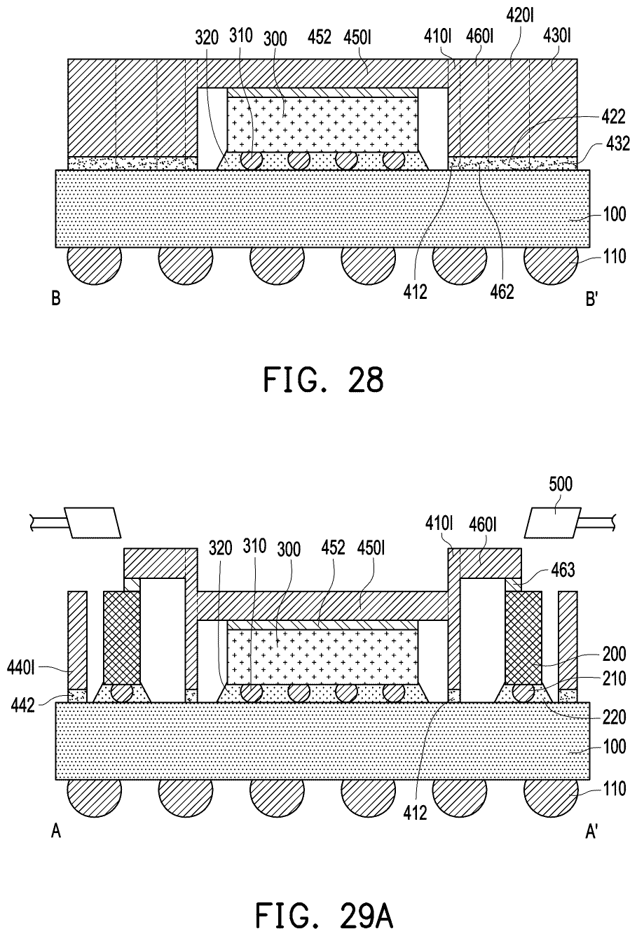

In some embodiments, the height of the wall portion 410I differs (for example, is greater) from the height of the block portions 430I, as shown in FIGS. 26C and 27. In some embodiments, the first connection portions 420I have inclined top surfaces, as shown in FIG. 27. In some embodiments, the height of the wall portion 410I is equal to the height of the block portions 430I, and the top surfaces of the wall portion 410I, the first connection portions 420I, the block portions 430I, the lid portion 450I, and the extension portion 460I are in the same plane. In other words, the warpage control structure 400I has a flat top surface, as shown in FIG. 28.

In some embodiments, gaps exist between the first connection portions 420I and the substrate 100 and between the extension portion 460I and the substrate 100, as shown in FIGS. 26C and 27. In other embodiments, the first connection portions 420I are adhered to the substrate 100 by third adhesive layers 422, and the extension portion 460I is adhered to the substrate 100 by the seventh adhesive layers 462, as depicted in FIG. 28.

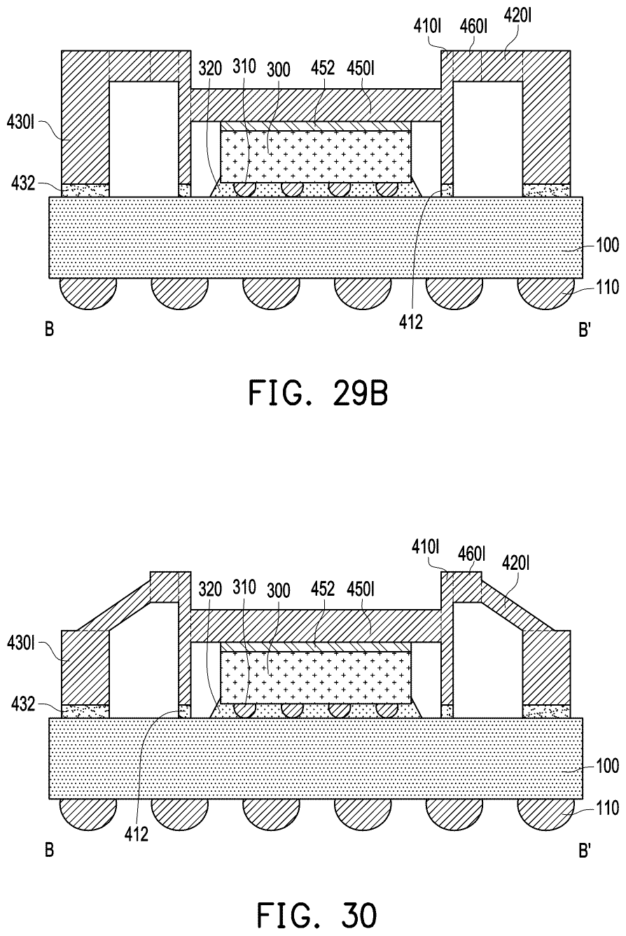

FIGS. 29A and 29B depict schematic cross-sectional views of a package in another embodiment. The top views of the packages in FIGS. 29A and 29B correspond to FIG. 26A, with FIGS. 29A and 29B aligning with the positions of line A-A′ and line B-B′ in FIG. 26A, respectively.

The package in FIGS. 29A and 29B is similar to the package 10I in FIGS. 26A to 26C, with the difference being that in FIGS. 29A and 29B, the height of the second package components 200 is greater than that of the first package component 300, and the top surfaces of the wall portion 410I, the first connection portions 420I, the block portions 430I, and the extension portion 460I are higher than the top surface of the lid portion 450I.

In FIG. 29B, the height of the block portions 430I is the same as the height of the wall portion 410I, but this disclosure is not limited thereto. In other embodiments, the height of the block portions 430I is different (e.g., lower) than the height of the wall portion 460I, as shown in FIG. 30.

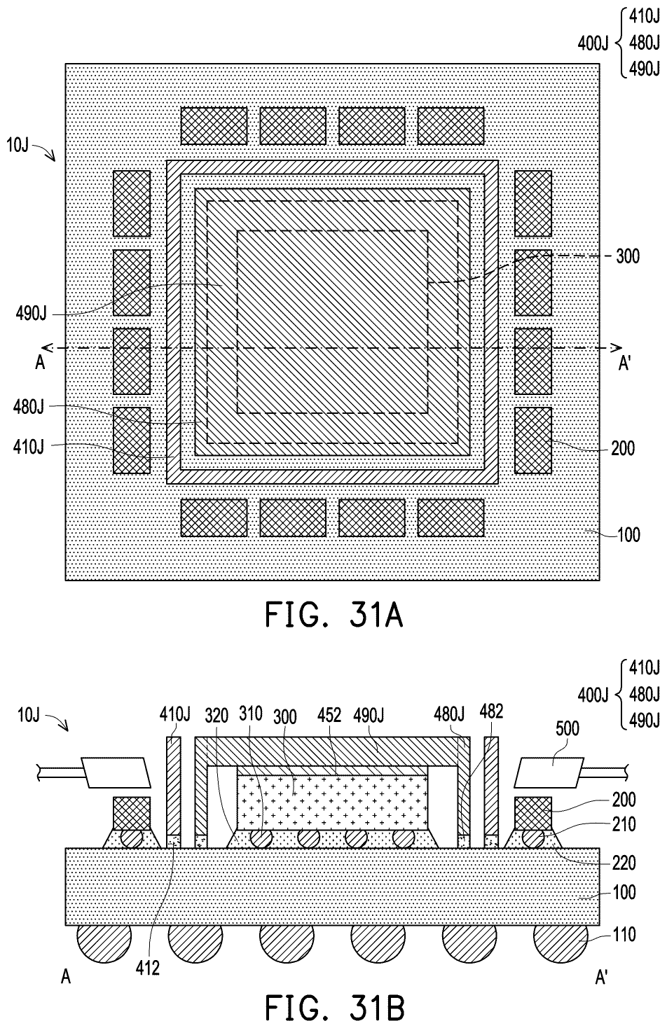

FIGS. 31A and 31B illustrate top and cross-sectional views of a package 10J in accordance with an embodiment of the disclosure. The package 10J in FIGS. 31A and 31B is similar to the package 10A in FIGS. 1A and 1B, with the difference being that in the package 10J, the warpage control structure 400J (referred to as a supporting structure in some embodiments) includes a wall portion 410J, a frame portion 480J, and a first heat dissipation portion 490J.

The frame portion 480J surrounds the first package component 300. Positioned between the wall portion 410J and the first package component 300, the frame portion 480J is encircled by the wall portion 410J. Together, the frame portion 480J and the wall portion 410J separate the first package component 300 from the second package components 200. The wall portion 410J is adhered to the substrate 100 using the first adhesive layer 412. The frame portion 480J is adhered to the substrate 100 using the eighth adhesive layer 482.

The first heat dissipation portion 490J is disposed above the first package component 300, and the first TIM layer 452 is located between the first heat dissipation portion 490J and the first package component 300.

In some embodiment, the frame portion 480J and the first heat dissipation portion 490J are integrally formed and made of the same material. The wall portion 410J is separate from the frame portion 480J and the first heat dissipation portion 490J and is made of a different material. For example, to improve thermal performance, a material with high thermal conductivity is used for the frame portion 480J and the first heat dissipation portion 490J. In other words, in some embodiments, the thermal conductivity of the frame portion 480J and the first heat dissipation portion 490J is higher than that of the wall portion 410J.

By designing the warpage control structure 400J with two separate structures of different materials (one structure includes the wall portion 410J, and the other includes the frame portion 480J and the first heat dissipation portion 490J), the design of the warpage control structure 400J becomes more flexible, making it easier to achieve the requirements of package coplanarity, thermal dissipation, and optical device outward connection.

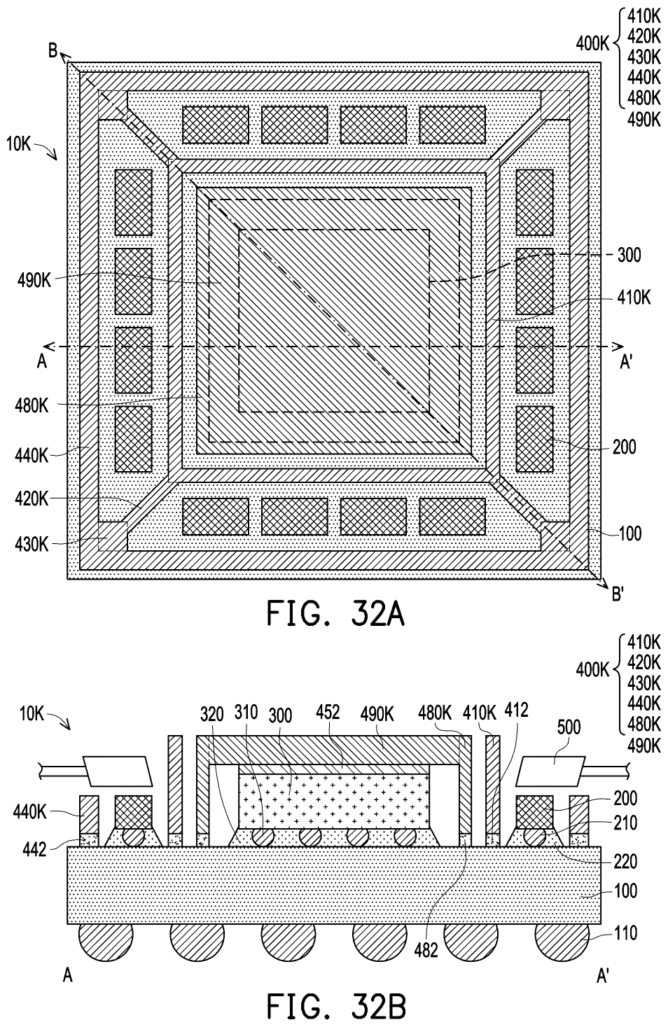

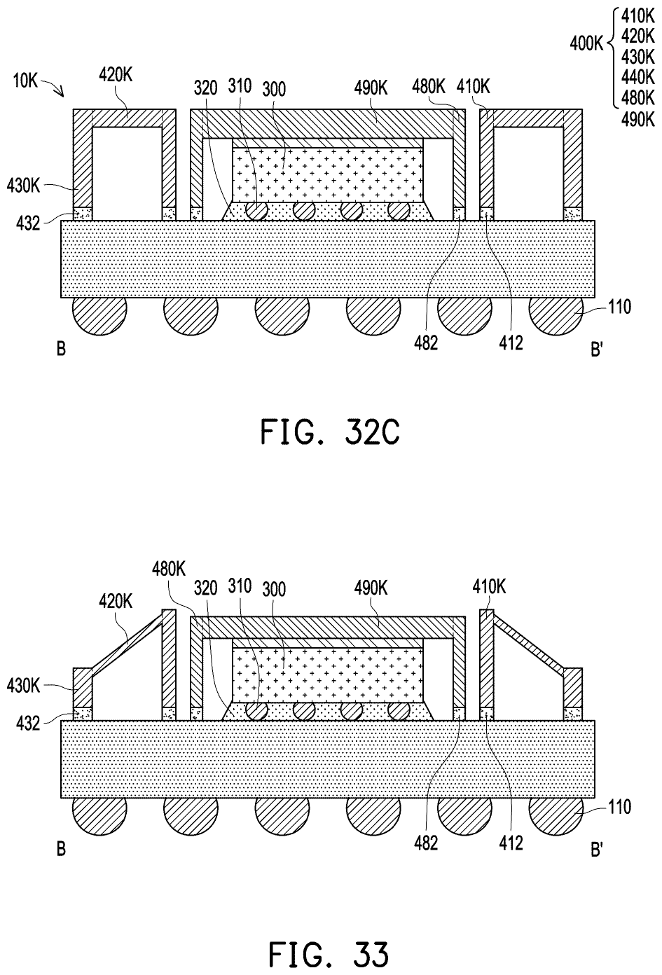

FIGS. 32A to 32C illustrate top and cross-sectional views of a package 10K in accordance with an embodiment of the disclosure. The package 10I in FIGS. 32A to 32C is similar to the package 10J in FIGS. 31A and 31B, with the difference being that in the package 10K, the warpage control structure 400K (referred to as a supporting structure in some embodiments) includes a wall portion 410K, a plurality of first connection portions 420K, a plurality of block portions 430K, a ring portion 440K, a frame portion 480K, and a first heat dissipation portion 490K.

Referring to FIGS. 32A to 32C, the frame portion 480K surrounds the first package component 300. Positioned between the wall portion 410K and the first package component 300, the frame portion 480K is encircled by the wall portion 410K. Together, the frame portion 480K and the wall portion 410K separate the first package component 300 from the second package components 200. The wall portion 410K is adhered to the substrate 100 using the first adhesive layer 412. The frame portion 480K is adhered to the substrate 100 using the eighth adhesive layer 482.

The first heat dissipation portion 490K is disposed above the first package component 300, and the first TIM layer 452 is located between the first heat dissipation portion 490K and the first package component 300.

The block portions 430K are respectively disposed near the corners of the substrate 100. The block portions 430K is used to increase the adhesive area between the warpage control structure 400K and the substrate 100, thereby enhancing the structural stability. The block portions 430K are adhered to the substrate 100 by the second adhesive layers 432.

The first connection portions 420K are individually connected to the block portions 430K and extend from the block portions 430K toward the wall portion 410K. In some embodiments, the first connection portions 420K connect the block portions 430K to the wall portion 410K. In some embodiments, the width of each first connection portion 420K is narrower than the width of each block portion 430K.

The ring portion 440K is connected to the block portions 430K. The ring portion 440K is near the edge of the substrate 100, and the second package components 200 are located between the ring portion 440K and the wall portion 410K. The ring portion 440K is attached to the substrate 100 by the fourth adhesive layer 442.

In some embodiment, the frame portion 480K and the first heat dissipation portion 490K are integrally formed and made of the same material. The wall portion 410K, the first connection portions 420K, the block portions 430K, and the ring portion 440K are integrally formed and made of the same material. For example, to improve thermal performance, a material with high thermal conductivity is used for the frame portion 480K and the first heat dissipation portion 490K. In other words, in some embodiments, the thermal conductivity of the frame portion 480K and the first heat dissipation portion 490K is higher than that of the wall portion 410K, the first connection portions 420K, the block portions 430K, and the ring portion 440K.

By designing the warpage control structure 400J with two separate structures of different materials (one structure includes the wall portion 410K, the first connection portions 420K, the block portions 430K, and the ring portion 440K, and the other includes the frame portion 480K and the first heat dissipation portion 490K), the design of the warpage control structure 400K becomes more flexible, making it easier to achieve the requirements of package coplanarity, thermal dissipation, and optical device outward connection.

FIGS. 32C to 35 depict schematic cross-sectional views of packages in different embodiments. The top views of the packages in FIGS. 32C to 35 correspond to FIG. 32A, and FIGS. 32C to 35 align with the position of line B-B′ in FIG. 32A.

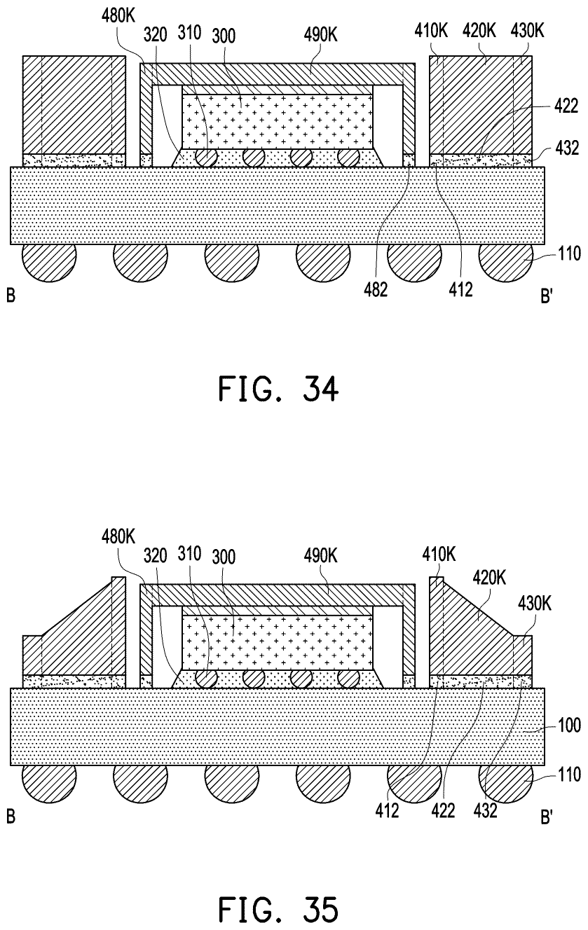

In some embodiments, the height of the wall portion 410K is equal to the height of the block portions 430K, and the top surfaces of the wall portion 410K, the first connection portions 420K, and the block portions 430K are in the same plane, as shown in FIGS. 32C and 34. In some embodiments, the height of the wall portion 410K differs (for example, is greater) from the height of the block portions 430K, and the first connection portions 420K have inclined top surfaces, as shown in FIGS. 33 and 35.

In some embodiments, gaps exist between the first connection portions 420K and the substrate 100, as shown in FIGS. 32C and 33. In other embodiments, the first connection portions 420K are adhered to the substrate 100 by third adhesive layers 422, as depicted in FIGS. 34 and 35.

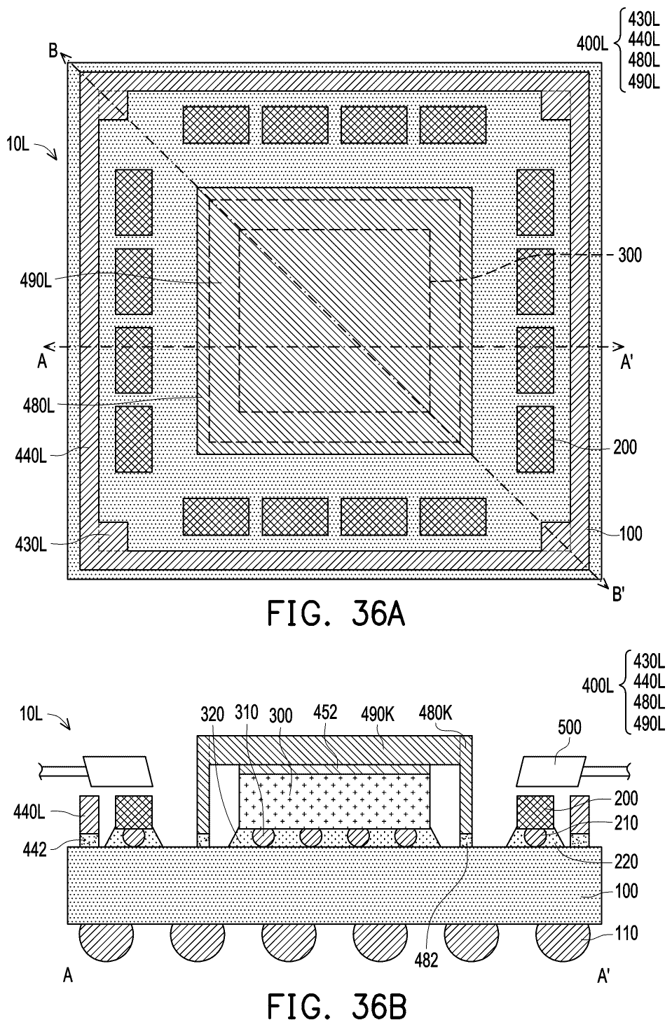

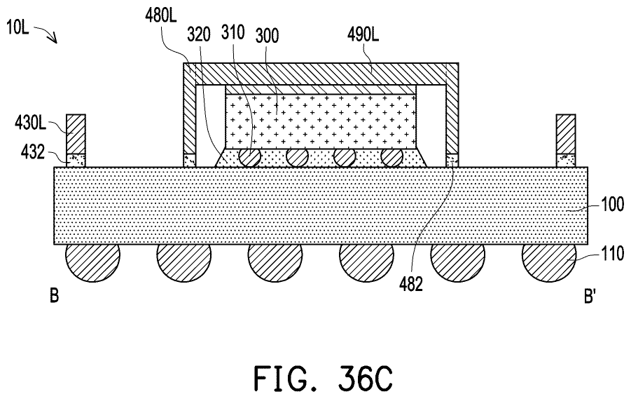

FIGS. 36A to 36C illustrate top and cross-sectional views of a package 10L in accordance with an embodiment of the disclosure. The package 10L in FIGS. 36A to 36C is similar to the package 10K in FIGS. 32A to 32C, with the difference being that in the package 10L, the warpage control structure 400L (referred to as a supporting structure in some embodiments) includes a plurality of block portions 430L, a ring portion 440L, a frame portion 480L, and a first heat dissipation portion 490L.

Referring to FIGS. 36A to 36C, the frame portion 480L surrounds the first package component 300. The frame portion 480L separates the first package component 300 from the second package components 200. The frame portion 480L is adhered to the substrate 100 using the eighth adhesive layer 482.

The first heat dissipation portion 490L is disposed above the first package component 300, and the first TIM layer 452 is located between the first heat dissipation portion 490L and the first package component 300.

The block portions 430L are respectively disposed near the corners of the substrate 100. The block portions 430L is used to increase the adhesive area between the warpage control structure 400L and the substrate 100, thereby enhancing the structural stability. The block portions 430L are adhered to the substrate 100 by second adhesive layers 432.

The ring portion 440L is connected to the block portions 430L. The ring portion 440L is near the edge of the substrate 100, and the second package components 200 are located between the ring portion 440L and the frame portion 480L. The ring portion 440L is attached to the substrate 100 by the fourth adhesive layer 442.

In some embodiment, the frame portion 480L and the first heat dissipation portion 490L are integrally formed and made of the same material. The block portions 430L and the ring portion 440L are integrally formed and made of the same material. For example, to improve thermal performance, a material with high thermal conductivity is used for the frame portion 480L and the first heat dissipation portion 490L. In other words, in some embodiments, the thermal conductivity of the frame portion 480L and the first heat dissipation portion 490L is higher than that of the block portions 430L and the ring portion 440L.

By designing the warpage control structure 400L with two separate structures of different materials (one structure includes the block portions 430L and the ring portion 440L, and the other includes the frame portion 480L and the first heat dissipation portion 490L), the design of the warpage control structure 400L becomes more flexible, making it easier to achieve the requirements of package coplanarity, thermal dissipation, and optical device outward connection.

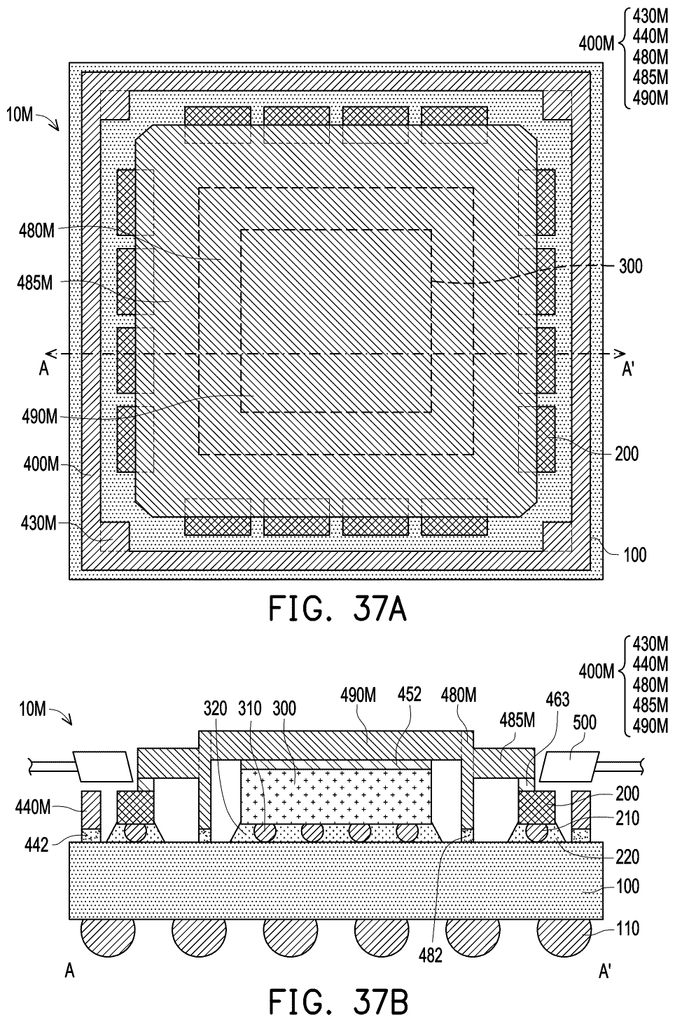

FIGS. 37A to 37C illustrate top and cross-sectional views of a package 10M in accordance with an embodiment of the disclosure. The package 10M in FIGS. 37A to 37C is similar to the package 10L in FIGS. 36A to 36C, with the difference being that in the package 10M, the warpage control structure 400M (referred to as a supporting structure in some embodiments) includes a plurality of block portions 430M, a ring portion 440M, a frame portion 480M, a first heat dissipation portion 490M, and a second heat dissipation portion 485M.

Referring to FIGS. 37A to 37C, the frame portion 480M surrounds the first package component 300. The frame portion 480M separates the first package component 300 from the second package components 200. The frame portion 480M is adhered to the substrate 100 using the eighth adhesive layer 482.

The first heat dissipation portion 490M is disposed above the first package component 300, and the first TIM layer 452 is located between the first heat dissipation portion 490M and the first package component 300.

The second heat dissipation portion 485M is connected to the frame portion 480M. The second heat dissipation portion 485M is disposed above the second package components 200, and a plurality of second TIM layers 463 are disposed between the second heat dissipation portion 485M and the second package components 200.

The block portions 430M are respectively disposed near the corners of the substrate 100. The block portions 430M is used to increase the adhesive area between the warpage control structure 400M and the substrate 100, thereby enhancing the structural stability. The block portions 430M are adhered to the substrate 100 by second adhesive layers 432.

The ring portion 440M is connected to the block portions 430M. The ring portion 440M is near the edge of the substrate 100, and the second package components 200 are located between the ring portion 440M and the frame portion 480M. The ring portion 440M is attached to the substrate 100 by the fourth adhesive layer 442.

In some embodiment, the frame portion 480M, the first heat dissipation portion 490M, and the second heat dissipation portion 485M are integrally formed and made of the same material. The block portions 430M and the ring portion 440M are integrally formed and made of the same material. For example, to improve thermal performance, a material with high thermal conductivity is used for the frame portion 480M, the first heat dissipation portion 490M, and the second heat dissipation portion 485M. In other words, in some embodiments, the thermal conductivity of the frame portion 480M, the first heat dissipation portion 490M, and the second heat dissipation portion 485M is higher than that of the block portions 430M and the ring portion 440M.

By designing the warpage control structure 400M with two separate structures of different materials (one structure includes the block portions 430M and the ring portion 440M, and the other includes the frame portion 480M, the first heat dissipation portion 490M, and the second heat dissipation portion 485M), the design of the warpage control structure 400M becomes more flexible, making it easier to achieve the requirements of package coplanarity, thermal dissipation, and optical device outward connection.

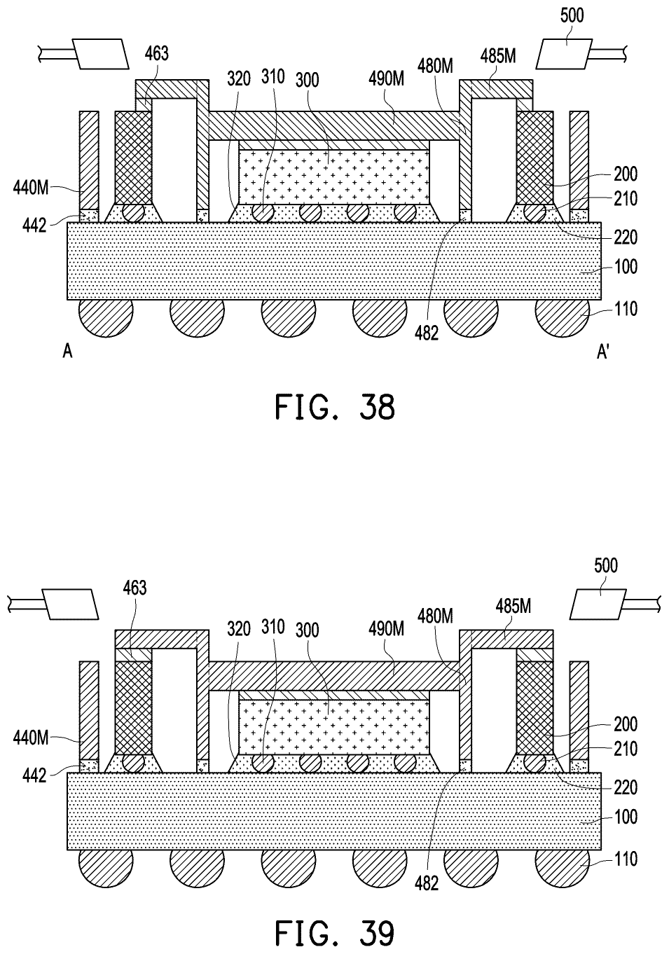

In FIG. 37B, the height of the second package components 200 is less than the height of the first package component 300, but the disclosure is not limited thereto. In other embodiments, the height of the second package components 200 is greater than the height of the first package component 300, as shown in FIG. 38.

In some embodiments, the warpage control structure 400M exposes at least part of the top surface of the second package component 200. Therefore, the second package component 200 may receive light signals on the top surface through a grating coupler (not shown). In other embodiments, the second package components 200 may receive light signals on the side surface through an edge coupler (not shown). Thus, the warpage control structure 400M may cover the entire top surface of the second package components 200 while exposing at least part of the side surface, as shown in FIG. 39.

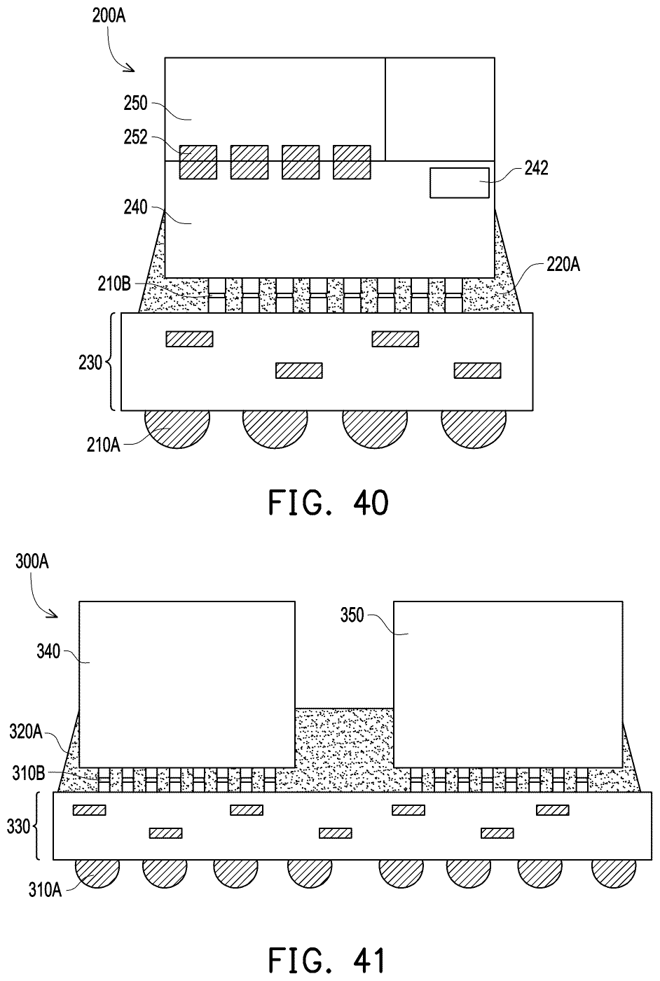

FIGS. 40 and 41 illustrate cross-sectional views of package components 200A and 300A in accordance with an embodiment of the disclosure. In any of the embodiments shown in FIGS. 1A to 39, the structure of the second package component 200 may be the same as the package component 200A in FIG. 40, but the disclosure is not limited to this. The second package component 200 in FIGS. 1A to 39 may also be other package structures that include a PIC. Additionally, in any of the embodiments shown in FIGS. 1A to 39, the structure of the first package component 300 may be the same as the package component 300A in FIG. 41, but the disclosure is not limited to this. The first package component 300 in FIGS. 1A to 39 may also be other package structures that include logic and/or memory devices.

Referring to FIG. 40, the package component 200A includes an electronic die 250, a photonic die 240, and an optionally interposer 230. The electronic die 250 includes an electronic integrated circuit (EIC), and the photonic die 240 includes a photonic integrated circuit (PIC). The electronic die 250 is electrically connected to the photonic die 240 by an interconnect structure 252. Although one electronic die 240 is illustrated, a plurality of electronic dies 38 may be bonded to the photonic die 240. The photonic die 240 includes an optical coupler 242 for receiving/transmitting optical signals.

In this embodiment, the photonic die 240 is bonded to the interposer 230 by bumps 210B and further electrically connected to the package substrate (not shown in FIG. 40) through connectors 210A, but the disclosure is not limited thereto. In other embodiments, the bumps 210B and interposer 230 may be omitted, and a redistribution structure (not shown) and the connectors 210A may be sequentially formed on the photonic die 240, and the photonic die 240 is electrically connected to the package substrate by the redistribution structure and the connectors 210A. In FIG. 40, an underfill material layer 220A is used to protect the bumps 210B.

Referring to FIG. 41, the package component 300A includes a first electronic die 340, a second electronic die 350, and an optionally interposer 330. In some embodiments, the package component 300A may include more or fewer electronic dies.

The first electronic die 340 and the second electronic die 350 are logic devices and/or memory devices. The logic devices may include ASIC dies, CPUs, GPUs, SoCs, microcontrollers, or the like. The memory devices may include a HMC device, a HBM device, or the like.

In this embodiment, the first electronic die 340 and the second electronic die 350 are bonded to the interposer 330 by bumps 310B and further electrically connected to the package substrate (not shown in FIG. 41) through connectors 310A, but the disclosure is not limited thereto. In other embodiments, the bumps 310B and interposer 330 may be omitted, and a redistribution structure (not shown) and the connectors 310A may be sequentially formed on the first electronic die 340 and the second electronic die 350, and the first electronic die 340 and the second electronic die 350 are electrically connected to the package substrate by the redistribution structure and the connectors 310A. In FIG. 41, an underfill material layer 320A is used to protect the bumps 310B.

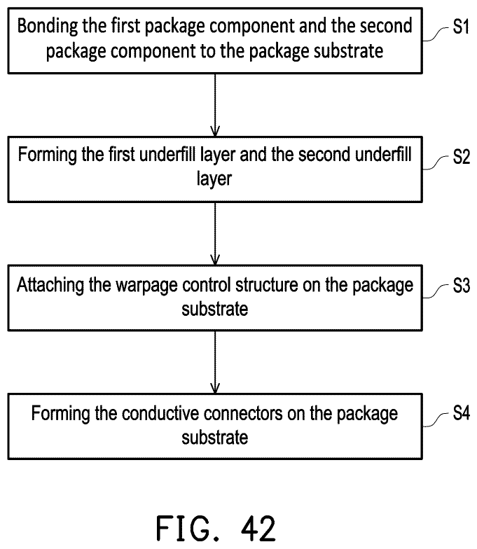

FIG. 42 is a flow chart of a method of manufacturing a package in accordance with some embodiments.

In step S1, the first package component (e.g., the first package component 300 in the embodiments of FIGS. 1A to 39) and the second package component (e.g., the second package component 200 in the embodiments of FIGS. 1A to 39) are bonded to the package substrate (e.g., the substrate 100 in the embodiments of FIGS. 1A to 39).

In step S2, the first underfill layer (e.g., the first underfill layer 320 in the embodiments of FIGS. 1A to 39) is formed between the first package component and the package substrate, and the second underfill layer (e.g., the second underfill layer 220 in the embodiments of FIGS. 1A to 39) is formed between the second package component and the package substrate.

In step S3, the warpage control structure (e.g., the warpage control structures 400A to 400M in the embodiments of FIGS. 1A to 39) is attached to the package substrate. The warpage control structure, the first package component, and the second package component are located on the same side of the package substrate, and the warpage control structure separates the first package component from the second package component.

In step S4, the conductive connectors (e.g., the conductive connectors 110 in the embodiments of FIGS. 1A to 39) are formed on the side of the package substrate opposite to the warpage control structure.

In one exemplary aspect, a package includes a substrate, a first package component, second package components, and a supporting structure. The first package component and the second package components are bonded to the substrate, and the second package components are electrically connected to the first package component. Each second package component comprises an optical coupler. The supporting structure is attached on the substrate. At least a portion of the supporting structure is laterally located between the first package component and the second package components.

In another exemplary aspect, a fabrication method of a package includes the following steps. A first die and a plurality of second die are bonded to a substrate, wherein the plurality of second dies are arranged around the first die. A warpage control structure is attached on the substrate. The warpage control structure laterally separates the first die from the plurality of second dies. A first thermal interface material layer is located between the warpage control structure and the first die, and a second thermal interface material layer is located between the warpage control structure and the plurality of second dies.

In yet another exemplary aspect, a package includes a substrate, a first semiconductor device, a first underfill layer, a second semiconductor device, a second underfill layer, and a supporting structure. The first semiconductor device and the second semiconductor device are bonded to the substrate. The first underfill layer is disposed between the substrate and the first semiconductor device. The second semiconductor device is bonded to the substrate and electrically connected to the first semiconductor device by the substrate. The second semiconductor device includes a photonic integrated circuit. The second underfill layer is disposed between the substrate and the second semiconductor device. The supporting structure is attached on the substrate by a first adhesive layer. The first adhesive layer is laterally located between the first underfill layer and the second underfill layer.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package, comprising:
a substrate;
a first package component bonded to the substrate;
a plurality of second package components bonded to the substrate and electrically connected to the first package component, wherein each of the plurality of second package components comprises an optical coupler; and
a supporting structure attached on the substrate, wherein at least a portion of the supporting structure is laterally located between the first package component and the plurality of second package components.

2. The package according to claim 1, wherein the supporting structure comprises:
a wall portion surrounding the first package component.

3. The package according to claim 2, wherein the supporting structure comprises:
a plurality of block portions, respectively disposed near corners of the substrate, wherein the plurality of block portions are attached on the substrate; and
a plurality of first connection portions, respectively connected to the plurality of block portions, and extending from the plurality of block portions toward the wall portion.

4. The package according to claim 3, wherein the supporting structure comprises:
a ring portion, connected to the plurality of block portions, wherein the plurality of second package components are located between the ring portion and the wall portion, and the ring portion is attached on the substrate.

5. The package according to claim 2, wherein the supporting structure comprises:
a lid portion connected to the wall portion, wherein the lid portion is disposed above the first package component, and a first thermal interface material layer is located between the lid portion and the first package component.

6. The package according to claim 5, wherein the supporting structure comprises:
an extension portion is disposed above the plurality of second package components.

7. The package according to claim 6, wherein the extension portion is connected to the wall portion.

8. A fabrication method of a package, comprising:
bonding a first die and a plurality of second die to a substrate, wherein the plurality of second dies are arranged around the first die; and
attaching a warpage control structure on the substrate, wherein the warpage control structure laterally separates the first die from the plurality of second dies, wherein a first thermal interface material layer is located between the warpage control structure and the first die, and a second thermal interface material layer is located between the warpage control structure and the plurality of second dies.

9. The fabrication method according to claim 8, wherein the warpage control structure comprises:
a first heat dissipation portion disposed above the first die and the first thermal interface material layer; and
a frame portion, connected to the first heat dissipation portion and attached on the substrate, wherein the frame portion is located between the first die and the plurality of second dies.

10. The fabrication method according to claim 9, wherein the warpage control structure comprises:
a wall portion, surrounding the frame portion and separated from the frame portion, wherein a material of the wall portion is different from a material of the frame portion.

11. The fabrication method according to claim 9, wherein the warpage control structure comprises:
a ring portion, wherein the plurality of second dies are located between the ring portion and the frame portion, wherein a material of the ring portion is different from a material of the frame portion.

12. The fabrication method according to claim 9, wherein the warpage control structure comprises:
a second heat dissipation portion disposed above the plurality of second dies, wherein the second heat dissipation portion is connected to the frame portion.

13. The fabrication method according to claim 8, further comprises:
forming a first underfill layer between the substrate and the first die; and
forming a second underfill layer disposed between the substrate and at least one of the plurality of second dies, wherein the first underfill layer is separated from the second underfill layer.

14. The fabrication method according to claim 8, wherein each of the plurality of second dies comprises a photonic integrated circuit.

15. A package, comprising:
a substrate;
a first semiconductor device bonded to the substrate;
a first underfill layer disposed between the substrate and the first semiconductor device;
a second semiconductor device bonded to the substrate, wherein the second semiconductor device is electrically connected to the first semiconductor device by the substrate, and the second semiconductor device comprises a photonic integrated circuit;
a second underfill layer disposed between the substrate and the second semiconductor device; and
a supporting structure attached on the substrate by a first adhesive layer, wherein the first adhesive layer is laterally located between the first underfill layer and the second underfill layer.

16. The package according to claim 15, wherein the supporting structure comprises:
a wall portion surrounding the first semiconductor device, wherein the wall portion is attached on the substrate by the first adhesive layer.

17. The package according to claim 16, wherein the supporting structure comprises:
a plurality of block portions, respectively disposed near corners of the substrate, wherein the plurality of block portions are attached on the substrate by second adhesive layers; and
a plurality of first connection portions, respectively connected to the plurality of block portions, and extending from the plurality of block portions toward the wall portion.

18. The package according to claim 16, wherein the supporting structure comprises:
a first heat dissipation portion disposed above the first semiconductor device, and a first thermal interface material layer is located between the first heat dissipation portion and the first semiconductor device; and
a frame portion, connected to the first heat dissipation portion and attached on the substrate, wherein the frame portion is located between the first semiconductor device and the wall portion, and wherein a material of the wall portion is different from a material of the frame portion.

19. The package according to claim 16, wherein the supporting structure comprises:
a lid portion connected with the wall portion, wherein the lid portion is disposed above the first semiconductor device, and a first thermal interface material layer is located between the lid portion and the first semiconductor device.

20. The package according to claim 19, wherein the supporting structure comprises:
an extension portion attached on the second semiconductor device, wherein the extension portion is disposed above the second semiconductor device, and a second thermal interface material layer is located between the extension portion and the second semiconductor device.
